(19) United States
(12) Patent Application Publication
(10) Pub. No.: US 2026/0076072 A1
(43) Pub. Date: Mar. 12, 2026

(54) MOTHER SUBSTRATE INCLUDING DISPLAY CELLS, AND METHOD FOR FABRICATING DISPLAY DEVICE

(71) Applicant: Samsung Display Co., Ltd., Yongin-si (KR)

(72) Inventors: Go Un HAN, Yongin-si (KR); Sang Ik LEE, Yongin-si (KR); Hyo Jun HA, Yongin-si (KR); Yun Hee JU, Yongin-si (KR); Hye Rhee HAN, Yongin-si (KR)

(21) Appl. No.: 19/289,668

(22) Filed: Aug. 4, 2025

(30) Foreign Application Priority Data
Sep. 9, 2024 (KR) 10-2024-0122088

(51) Int. Cl. H10K 59/80; H10K 71/80

(52) U.S. Cl. CPC H10K 59/873; H10K 71/80

(57) ABSTRACT

A mother substrate including a plurality of display cells, and a method for fabricating a display device are disclosed. The mother substrate may include a support substrate, a first organic film on a surface of the support substrate, a first inorganic film arranged on the first organic film and covering an edge of the first organic film, a second organic film on the first inorganic film, a second inorganic film arranged on the second organic film and covering an edge of the second organic film, a plurality of display cells on the second inorganic film, and an encapsulation cover layer on a first inorganic encapsulation area where the first inorganic film and the second inorganic film contact each other. The encapsulation cover layer may be more inward than the edge of the first organic film on the substrate.

### CROSS-REFERENCE TO RELATED APPLICATION

The present application claims priority to and the benefit of Korean Patent Application No. 10-2024-0122088, filed on Sep. 9, 2024, in the Korean Intellectual Property Office, the entire disclosure of which is incorporated herein by reference.

### BACKGROUND

### 1. Field

One or more embodiments of the present disclosure relate to a mother substrate including a plurality of display cells, a method for fabricating a display device, and an electronic device including at least a portion of the mother substrate (e.g., the display device).

### 2. Description of the Related Art

With the advancement of communication technology and media, display devices are used to display images in one or more suitable places and/or environments. For example, one or more types (kinds) of display devices, such as liquid-crystal display (LCD) devices and/or organic light-emitting diode (OLED) display devices, are widely used.

During the process of fabricating organic light-emitting diode display devices, a portion of an inorganic film may fall off due to physical contact with the fabrication equipment and/or high-pressure spray of a cleaning liquid from cleaning equipment. If (e.g., when) this happens, a seam may be formed in an encapsulation layer that encapsulates organic light-emitting diodes due to a transparent inorganic particle, which is the portion of the inorganic film. If (e.g., when) moisture and/or oxygen 1 permeates through the seam, the organic light-emitting diode may be oxidized and may not be able to emit light.

### SUMMARY

One or more aspects of embodiments of the present disclosure are directed toward a mother substrate including a plurality of display cells that may prevent particles which may be generated (or reduce a degree to or occurrence of which particles are formed or generated) if (e.g., when) a cover layer on a first organic film is melted in a carbonization process for a first organic film during a process of fabricating organic light-emitting diode display devices. For example, one or more aspects of embodiments of the present disclosure are directed toward a mother substrate including a plurality of display cells that may prevent or reduce particles generated if (e.g., when) a cover layer on a first organic film is melted in a carbonization process during the fabrication of organic light-emitting diode display devices.

One or more aspects of embodiments of the present disclosure are also directed toward a method for fabricating a display device including a plurality of display cells that may prevent particles which may be generated (or reduce a degree to or occurrence of which particles are formed or generated) if (e.g., when) a cover layer on a first organic film is melted in a carbonization process for a first organic film during a process of fabricating organic light-emitting diode display devices. For example, one or more aspects of embodiments of the present disclosure are directed toward a method for fabricating a display device including a plurality of display cells that may prevent or reduce particles generated if (e.g., when) a cover layer on a first organic film is melted in a carbonization process during the fabrication of organic light-emitting diode display devices.

Additional aspects of embodiments will be set forth in part in the description which follows and, in part, will be apparent from the description or may be learned by practice of the presented embodiments of the disclosure.

In one or more embodiments, a mother substrate includes a support substrate, a first organic film on a surface of the support substrate (e.g., on the support substrate), a first inorganic film arranged on the first organic film and covering an edge of the first organic film, a second organic film on the first inorganic film, a second inorganic film arranged on the second organic film and covering an edge of the second organic film, a plurality of display cells on the second inorganic film, and an encapsulation cover layer on a first inorganic encapsulation area where the first inorganic film and the second inorganic film contact each other. The encapsulation cover layer is arranged more inward than the edge of the first organic film. The phrase “more inward than the edge of the first organic film” refers to that the encapsulation cover layer may be positioned or arranged closer to the center of the substrate compared to the edge of the first organic film. For example, the encapsulation cover layer may not extend to or beyond the edge of the first organic film but may be instead located or arranged further inside, towards the middle of the substrate. This positioning or arrangement may help protect the encapsulation area and prevent the cover layer from being exposed to processes that may cause it to melt or generate particles. For example, the encapsulation cover layer may be positioned or arranged more inward relative to the edge of the first organic film on the support substrate or the mother substrate. The encapsulation cover layer may not cover the edge of the first organic film.

The encapsulation cover layer may overlap the edge of the second organic film in a thickness direction of the support substrate.

The encapsulation cover layer may overlap the first organic film in a thickness direction of the support substrate.

The first inorganic encapsulation area may be arranged more to inward than the edge of the first organic film.

The mother substrate may further include an auxiliary cover layer spaced and/or apart (e.g., spaced apart or separated) from the encapsulation cover layer and arranged more outward than the edge of the first organic film. For example, this refers to that the auxiliary cover layer may be located or arranged closer to the outer edge of the substrate compared to the edge of the first organic film, providing additional protection and structural integrity to the encapsulation area.

The auxiliary cover layer may be on the first inorganic film.

The auxiliary cover layer may be arranged more inward than the edge of the first inorganic film. For example, this refers to that the auxiliary cover layer may not extend to or beyond the edge of the first inorganic film but may be instead located or arranged further inside, towards the middle of the substrate. This positioning or arrangement may help protect the encapsulation area and prevent the cover layer from being exposed to processes that may cause it to melt or generate particles.

The encapsulation cover layer may include a first encapsulation cover layer that overlaps with the edge of the second organic film in a thickness direction of the support substrate and a second encapsulation cover layer that is spaced and/or apart (e.g., spaced apart or separated) from the first encapsulation cover layer and that does not overlap with the second organic film in the thickness direction of the support substrate.

The second encapsulation cover layer may cover an edge of the second inorganic film.

The encapsulation cover layer may include an organic material having lower heat resistance than the first organic film.

In one or more embodiments, a mother substrate includes a support substrate, a first organic film on a surface of the support substrate (e.g., on the support substrate), a first inorganic film arranged on the first organic film and covering an edge of the first organic film, a second organic film on the first inorganic film, a second inorganic film arranged on the second organic film and covering an edge of the second organic film, a plurality of display cells on the second inorganic film, and an encapsulation cover layer on a first inorganic encapsulation area where the first inorganic film and the second inorganic film contact each other. The encapsulation cover layer may include a plurality of encapsulation cover layers spaced and/or apart (e.g., spaced apart or separated) from one another, and the plurality of encapsulation cover layers may be arranged more inward than an edge of the first inorganic film and an edge of the second inorganic film.

The plurality of encapsulation cover layers may include a first encapsulation cover layer that overlaps the edge of the first organic film in a thickness direction of the support substrate.

The plurality of encapsulation cover layers may further include a second encapsulation cover layer that is arranged more outward than the edge of the first organic film. For example, this refers to that the second encapsulation cover layer may be located or arranged closer to the outer edge of the substrate compared to the edge of the first organic film, providing additional protection and structural integrity to the encapsulation area.

The plurality of encapsulation cover layers may include a third encapsulation cover layer that is arranged more inward than the edge of the first organic film.

The first encapsulation cover layer, the second encapsulation cover layer, and the third encapsulation cover layer may be spaced and/or apart (e.g., spaced apart or separated) from one another.

The first encapsulation cover layer, the second encapsulation cover layer, and the third encapsulation cover layer may include substantially the same organic material.

The first inorganic encapsulation area may include a first region that contacts the support substrate and is flat (e.g., substantially flat), a second region that contacts the first organic film and is flat (e.g., substantially flat), and a third region that is between the first region and the second region. The first encapsulation cover layer may be on the first region, the second encapsulation cover layer may be on the third region, and the third encapsulation cover layer may be on the second region.

In one or more embodiments, a method for fabricating a display device includes sequentially forming or arranging a first organic film, a first inorganic film, a second organic film, and a second inorganic film on a support substrate, forming or arranging a plurality of display cells and an encapsulation cover layer on the second inorganic film, separating the support substrate from the first organic film, and cutting the plurality of display cells. The forming or arranging of the plurality of display cells and the encapsulation cover layer on the second inorganic film may include forming or arranging the encapsulation cover layer on the first inorganic encapsulation area where the first inorganic film not covered by the second organic film and the second inorganic film contact each other. The encapsulation cover layer may be arranged more inward than an edge of the first organic film.

The separating of the support substrate from the first organic film may include inserting a cutting unit between the support substrate and the first organic film, and cutting, by the cutting unit, between the support substrate and the first organic film along the first organic film.

The forming or arranging of the plurality of display cells and the encapsulation cover layer on the second inorganic film may include forming or arranging thin-film transistors on the second inorganic film, concurrently (e.g., simultaneously) forming or arranging at least one planarization film and the encapsulation cover layer on the thin-film transistors with an organic material, and forming or arranging light-emitting elements on the at least one planarization film and forming or arranging an encapsulation layer to encapsulate the light-emitting elements.

The forming or arranging of the plurality of display cells and the encapsulation cover layer on the second inorganic film may include forming or arranging thin-film transistors on the second inorganic film, forming or arranging at least one planarization film that covers the thin-film transistors, and forming or arranging a first electrode of each of light-emitting elements on the at least one planarization film, concurrently (e.g., simultaneously) forming or arranging a pixel-defining layer that covers an edge of the first electrode of each of the light-emitting elements and the encapsulation cover layer using an organic material, and forming or arranging an emissive layer and a second electrode of each of the light-emitting elements on the first electrode of each of the light-emitting elements exposed and not covered by the pixel-defining layer, and forming or arranging an encapsulation layer to encapsulate the light-emitting elements.

According to one or more embodiments of a mother substrate including a plurality of display cells and a method for fabricating a display device, an encapsulation cover layer may be formed or arranged in an area where inorganic films having relatively weak bonding strength contact each other. By doing so, it may be feasible to prevent one or more mechanical parts of the equipment or a mask from contacting the area (or reduce a degree to or occurrence of which one or more mechanical parts of the equipment or a mask contact the area) where the inorganic films contact each other during the fabrication process. Accordingly, damage (or a degree or occurrence of damage) to the area between the inorganic films having weak bonding strength may be reduced, thereby preventing particles from falling off from the area between the inorganic films (or reducing a degree to or occurrence of which particles fall off from the area between the inorganic films). As a result, it may be feasible to prevent transparent inorganic particles that fall off from the area between the inorganic films from bouncing off to a pixel-defining layer (or reduce a degree to or occurrence of which transparent inorganic particles that fall off from the area between the inorganic films bounce off to a pixel-defining layer) and in turn prevent pixel defects (or reduce a degree or occurrence of pixel defects).

According to one or more embodiments of a mother substrate including a plurality of display cells and a method for fabricating a display device, an encapsulation cover layer may be further formed or arranged in an area where a support substrate and a first inorganic film contact each other. Accordingly, it may be feasible to reduce damage (or a degree or occurrence of damage) to a single inorganic film (e.g., the first inorganic film) in the fabrication process, thereby preventing particles from falling off from the single inorganic film (or reducing a degree to or occurrence of which particles fall off from the single inorganic film). As a result, it may be feasible to prevent transparent inorganic particles that fall off from the single inorganic film from bouncing off to a pixel-defining layer (or reduce a degree to or occurrence of which transparent inorganic particles that fall off from the single inorganic film bounce off to a pixel-defining layer) and in turn prevent pixel defects (or reduce a degree or occurrence of pixel defects).

According to one or more embodiments of a mother substrate including a plurality of display cells and a method for fabricating a display device, an encapsulation cover layer arranged in the area between the inorganic films may be arranged more inward than the edge of a first organic film having higher heat resistance. Accordingly, the encapsulation cover layer may not be melted even in a laser process for carbonizing the first organic film. Therefore, it may be feasible to reduce particles (e.g., formation or generation of particles) of an organic film that may be previously generated due to melting of the encapsulation cover layer if (e.g., when) separating the first organic film from the support substrate. In one or more embodiments, by preventing excessive bonding (or reducing a degree or occurrence of excessive bonding) that may be previously generated due to melting of the encapsulation cover layer on the support substrate, it may be feasible to relatively easily separate the support substrate from the first organic film.

According to one or more embodiments, an electronic device includes at least a portion of the mother substrate (e.g., the electronic device may include the display device or may include one or more of the display cells) as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, and/or a head-mounted display (HMD).

However, aspects and features of embodiments of the present disclosure are not restricted to the one set forth herein. The above and other aspects and features of the present disclosure will become more apparent to one of ordinary skill in the art to which the present disclosure pertains by referencing the detailed description of the present disclosure given.

### BRIEF DESCRIPTION OF THE DRAWINGS

The above and other aspects and features of certain embodiments of the present disclosure will become more apparent and more readily appreciated from the following description of one or more embodiments, taken in conjunction with the accompanying drawings, in which:

FIG. 1 is a perspective view of a mother substrate including a plurality of display cells according to one or more embodiments of the present disclosure;

FIG. 2 is a layout diagram illustrating a support substrate, a plurality of display cells, a first inorganic encapsulation area, and a second inorganic encapsulation area of the mother substrate of FIG. 1;

FIG. 3 is a cross-sectional view illustrating a support substrate, a first organic film, a first inorganic film, a second organic film, a second inorganic film, a first inorganic encapsulation area, and a display cell of the mother substrate taken along the line A-A′ of FIG. 2;

FIG. 4 is a cross-sectional view illustrating area A of FIG. 3;

FIG. 5 is a cross-sectional view illustrating a seam that is formed or arranged if (e.g., when) a transparent inorganic particle in the first inorganic encapsulation area in FIG. 4 is placed on the encapsulation layer of a display cell;

FIG. 6 is a layout diagram illustrating a support substrate, a plurality of display cells, a first inorganic encapsulation area, a second inorganic encapsulation area, and an encapsulation cover layer of the mother substrate of FIG. 1;

FIG. 7 is a cross-sectional view illustrating a support substrate, a first organic film, a first inorganic film, a second organic film, a second inorganic film, a first inorganic encapsulation area, and a display cell of the mother substrate taken along the line B-B′ of FIG. 6;

FIG. 8 is a layout diagram illustrating a support substrate, a plurality of display cells, a first inorganic encapsulation area, a second inorganic encapsulation area, and an encapsulation cover layer of the mother substrate of FIG. 1;

FIG. 9 is a layout diagram illustrating area P of FIG. 8 in more detail;

FIG. 10 is a cross-sectional view illustrating a support substrate, a first organic film, a first inorganic film, a second organic film, a second inorganic film, a first inorganic encapsulation area, and a display cell of the mother substrate taken along the line C-C′ of FIG. 8;

FIG. 11 is a layout diagram illustrating area P of FIG. 8 in more detail;

FIG. 12 is a layout diagram illustrating area P of FIG. 8 in more detail;

FIG. 13 is a layout diagram illustrating area P of FIG. 8 in more detail;

FIG. 14 is a layout diagram illustrating a support substrate, a plurality of display cells, a first inorganic encapsulation area, a second inorganic encapsulation area, and an encapsulation cover layer of the mother substrate of FIG. 1;

FIG. 15 is a cross-sectional view illustrating a support substrate, a first organic film, a first inorganic film, a second organic film, a second inorganic film, a first inorganic encapsulation area, and a display cell of the mother substrate taken along the line D-D′ of FIG. 14;

FIG. 16 is a layout diagram illustrating a support substrate, a plurality of display cells, a first inorganic encapsulation area, a second inorganic encapsulation area, and an encapsulation cover layer of the mother substrate of FIG. 1;

FIGS. 17A and 17B are cross-sectional views each illustrating a support substrate, a first organic film, a first inorganic film, a second organic film, a second inorganic film, a first inorganic encapsulation area, and a display cell of the mother substrate taken along the line E-E′ of FIG. 16;

FIG. 18 is a flowchart illustrating a method for fabricating a mother substrate including a plurality of display cells according to one or more embodiments of the present disclosure;

FIGS. 19-24 are views illustrating a method for fabricating a mother substrate including a plurality of display cells according to one or more embodiments of the present disclosure.

### DETAILED DESCRIPTION

The aspects and features of embodiments of the present disclosure and methods of accomplishing the same may be understood more readily by reference to the detailed description of embodiments and the accompanying drawings. Hereinafter, the subject matter of the present disclosure will be described in more detail with reference to the accompanying drawings. The subject matter of the present disclosure, however, may be embodied in one or more suitable different forms and should not be construed as being limited to only the illustrated embodiments herein. Rather, these embodiments are provided as examples so that the present disclosure will be thorough and complete and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals, characters, and/or one or more (e.g., any suitable) combinations thereof refer to like elements throughout the accompanying drawings and the written description, and duplicative descriptions thereof may not be provided, and thus, descriptions thereof may not be repeated. Further, parts not related to the description of one or more embodiments may not be shown to make the description clear.

In the drawings, the relative sizes of elements, layers, and regions may be exaggerated for clarity. In one or more embodiments, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and/or the like of the elements, unless specified.

One or more embodiments are described herein with reference to sectional illustrations that are schematic illustrations of embodiments and/or intermediate structures. As such, variations from the shapes of the illustrations as a result, for example, of manufacturing techniques and/or tolerances, may be expected. Further, specific structural or functional descriptions disclosed herein are merely illustrative for the purpose of describing certain embodiments according to the present disclosure. Thus, one or more embodiments disclosed herein should not be construed as being limited to the particular illustrated shapes of regions, but are to include deviations in shapes that result from, for instance, manufacturing.

For example, an implanted region illustrated as a rectangle (e.g., a substantially rectangle) may have rounded or curved features and/or a gradient of implant concentration at its edges rather than a binary change from implanted to non-implanted region. Likewise, a buried region formed or provided by implantation may result in one or more implantations in the region between the buried region and the surface through which the implantation takes place. Thus, the regions illustrated in the drawings are schematic in nature and their shapes are not intended to illustrate the actual shape of a region of a device and are not intended to be limiting. In one or more embodiments, as those skilled in the art may realize, the described embodiments may be modified in one or more suitable different ways, all without departing from the spirit or scope of the present disclosure.

In the present disclosure, for the purposes of explanation, one or more specific details are set forth to provide a thorough understanding of one or more suitable embodiments. It is apparent, however, that one or more suitable embodiments may be practiced without these specific details or with one or more equivalent arrangements. In other instances, one or more structures and devices that are generally available or generally used are shown in block diagram form to avoid unnecessarily obscuring one or more suitable embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the drawings. It will be understood that the spatially relative terms are intended to encompass different orientations of the device in use or in operation, in addition to the orientation depicted in the drawings. For example, if (e.g., when) the device in the drawings is turned over, elements described as “below” or “beneath” or “under” other elements or features may then be oriented “above” the other elements or features. Thus, the example terms “below” and “under” may encompass both (e.g., simultaneously) an orientation of above and below. The device may be otherwise oriented (e.g., rotated 90 degrees or at other orientations) and the spatially relative descriptors used herein should be interpreted accordingly. Similarly, if (e.g., when) a first part is described as being arranged “on” a second part, this indicates that the first part is arranged at an upper side or a lower side of the second part without the limitation to the upper side thereof on the basis of the gravity direction.

Further, in the present disclosure, the phrase “on a plane” or “in a plan view” refers to viewing a target portion from the top, and the phrase “on a cross-section” refers to viewing a cross-section formed or provided by vertically cutting a target portion from the side.

It will be understood that if (e.g., when) an element, a layer, a region, or a component is referred to as being “formed on,” “arranged on,” “on,” “connected to,” or “coupled to” another element, layer, region, or component, it may be directly formed on, directly arranged on, directly on, directly connected to, or directly coupled to the other element, layer, region, or component, or indirectly formed on, indirectly arranged on, indirectly on, indirectly connected to, or indirectly coupled to the other element, layer, region, or component such that one or more intervening elements, layers, regions, or components may be present therebetween. For example, if (e.g., when) a layer, a region, or a component is referred to as being “electrically connected” or “electrically coupled” to another layer, region, or component, it may be directly electrically connected or coupled to the other layer, region, and/or component or intervening layers, regions, or components may be present therebetween. However, “directly connected/directly coupled” refers to one component directly connecting or coupling another component without an intermediate component present therebetween.

In one or more embodiments, other expressions describing relationships between components, such as “between,” “immediately between,” or “adjacent to,” and “directly adjacent to” may be construed similarly. In one or more embodiments, it will also be understood that if (e.g., when) an element or layer is referred to as being “between” two elements or layers, it may be the only element or layer between the two elements or layers, or one or more intervening elements or layers may also be present.

In the present disclosure, expressions, such as “at least one of,” “one of,” and “selected from among,” if (e.g., when) preceding a list of elements, modify the entire list of elements and do not modify the individual elements of the list. For example, “at least one of X, Y, and Z,” “at least one of X, Y, or Z,” and “at least one selected from among the group consisting of X, Y, and Z” may be construed as X only, Y only, Z only, a (e.g., any suitable) combination of two or more of X, Y, and Z, such as, for instance, XYZ, XYY, XZ, YZ, and ZZ, or a (e.g., any suitable) variation thereof. Similarly, the expression, such as “at least one of A and/or B” may include A, B, or A and B. As used herein, the term “and/or” includes any and all combinations of one or more of the associated listed items. For example, the expression, such as “A and/or B” may include A, B, or A and B. Further, the use of “may” if (e.g., when) describing embodiments of the present disclosure refers to “one or more embodiments of the present disclosure”.

It will be understood that, although the terms “first,” “second,” “third,” and/or the like may be used herein to describe one or more suitable elements, components, regions, layers, and/or sections, these elements, components, regions, layers, and/or sections should not be limited by these terms. These terms are used to distinguish one element, component, region, layer, or section from another element, component, region, layer, or section. Thus, a first element, a first component, a first region, a first layer, or a first section described herein may be termed a second element, a second component, a second region, a second layer, or a second section, without departing from the spirit and scope of the present disclosure.

In the examples, the x-axis, the y-axis, and/or the z-axis are not limited to three axes of a rectangular coordinate system and may be interpreted in a broader sense. For example, the x-axis, the y-axis, and the z-axis may be normal (e.g., perpendicular) to one another or may represent different directions that are not normal (e.g., perpendicular) to one another. The same applies for the first direction, the second direction, and/or the third direction.

The terminology used herein is for the purpose of describing particular embodiments only and is not intended to be limiting of the present disclosure. As used herein, the singular forms “a” and “an” are intended to include the plural forms as well, unless the context clearly indicates otherwise.

It will be further understood that the terms “have,” “having,” “includes,” and “including,” if (e.g., when) used in the present disclosure, specify the presence of the stated features, integers, steps, operations, elements, and/or components, but do not preclude the presence or addition of one or more other features, integers, steps, operations, elements, components, and/or groups thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “substantially,” “about,” “approximately,” and similar terms are used as terms of approximation and not as terms of degree and are intended to account for the inherent deviations in measured or calculated values that may be recognized by those of ordinary skill in the art. “About” or “approximately,” as used herein, is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations, or within ±30%, ±20%, ±10%, or ±5% of the stated value.

If (e.g., when) one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in the present disclosure is intended to include all higher numerical limitations subsumed therein. Accordingly, Applicant reserves the right to amend this specification, including the appended claims, to expressly recite any sub-range subsumed within the ranges expressly recited herein. All such ranges are intended to be inherently described in the present disclosure such that amending to expressly recite any such subranges may comply with the requirements of 35 U.S.C. § 112 (a) and 35 U.S.C. § 132 (a).

The electronic or electric devices and/or any other relevant devices or components (e.g., the mother substrate, the display device, the electronic device, the electronic apparatus, a device for manufacturing substantially the same, and/or the like) according to one or more embodiments of the present disclosure described herein may be implemented by utilizing any suitable hardware, firmware (e.g., an application-specific integrated circuit), software, and/or a (e.g., any suitable) combination of software, firmware, and hardware. For example, the one or more suitable components of these devices may be formed or provided on one integrated circuit (IC) chip and/or on separate IC chips. Further, the one or more suitable components of these devices may be implemented on a flexible printed circuit film, a tape carrier package (TCP), and/or a printed circuit board (PCB), and/or formed or provided on one substrate.

Further, the one or more suitable components of these devices may be a process or thread, running on one or more processors, in one or more computing devices, executing computer program instructions and interacting with other system components to perform the one or more suitable functionalities described herein. The computer program instructions are stored in a memory which may be implemented in a computing device by using a standard memory device, such as, for example, a random access memory (RAM). The computer program instructions may also be stored in other non-transitory computer readable media such as, for example, a CD-ROM, a flash drive, and/or the like. Also, a person of skill in the art should recognize that the functionality of one or more suitable computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have substantially the same meaning as generally understood by one of ordinary skill in the art to which the present disclosure belongs. It will be further understood that terms, such as those defined in dictionaries that are generally available, should be interpreted as having a meaning for example consistent with their meaning in the context of the relevant art and/or the present disclosure, and should not be interpreted in an idealized or overly formal sense, unless expressly so defined herein.

Hereinafter, one or more embodiments of the present disclosure will be described in more detail with reference to the accompanying drawings.

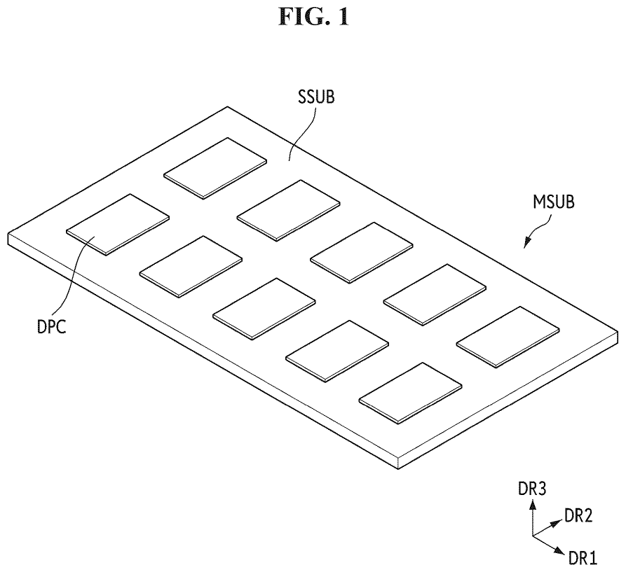

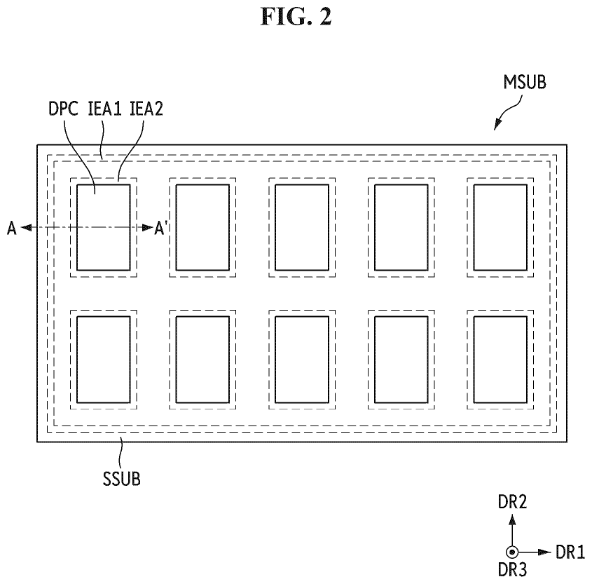

FIG. 1 is a perspective view of a mother substrate that includes a plurality of display cells according to one or more embodiments of the present disclosure. FIG. 2 is a layout diagram illustrating a support substrate, a plurality of display cells, a first inorganic encapsulation area, and a second inorganic encapsulation area of the mother substrate of FIG. 1.

Referring to FIGS. 1 and 2, a mother substrate MSUB according to one or more embodiments of the present disclosure may include a support substrate SSUB, a plurality of display cells DPC, a first inorganic encapsulation area IEA1, and a second inorganic encapsulation area IEA2.

The support substrate SSUB may be a rigid substrate that may support a plurality of display cells DPC during the fabrication of the plurality of display cells DPC. For example, the support substrate SSUB may be a glass substrate and/or a plastic substrate, such as polyethylene terephthalate (PET).

The support substrate SSUB may have a hexahedral shape (e.g., a substantially hexahedral shape) including a first surface that corresponds to the front face, a second surface that corresponds to the rear face, and a plurality of side surfaces. In one or more embodiments, the first surface and the second surface may have a rectangular shape (e.g., a substantially rectangular shape) having longer sides in the first direction DR1 and shorter sides in the second direction DR2. The first surface and the second surface may face (or may be opposed to) each other. In one or more embodiments, among the plurality of side surfaces, the upper surface and the lower surface may have a rectangular shape (e.g., a substantially rectangular shape) having longer sides in the first direction DR1 and shorter sides in the third direction DR3, and the left surface and the right surface may have a rectangular shape (e.g., a substantially rectangular shape) having longer sides in the second direction DR2 and shorter sides in the third direction DR3. However, the shape of the support substrate SUB is not limited to a hexahedron (e.g., a substantially hexahedron) and may have other shapes than a hexahedron.

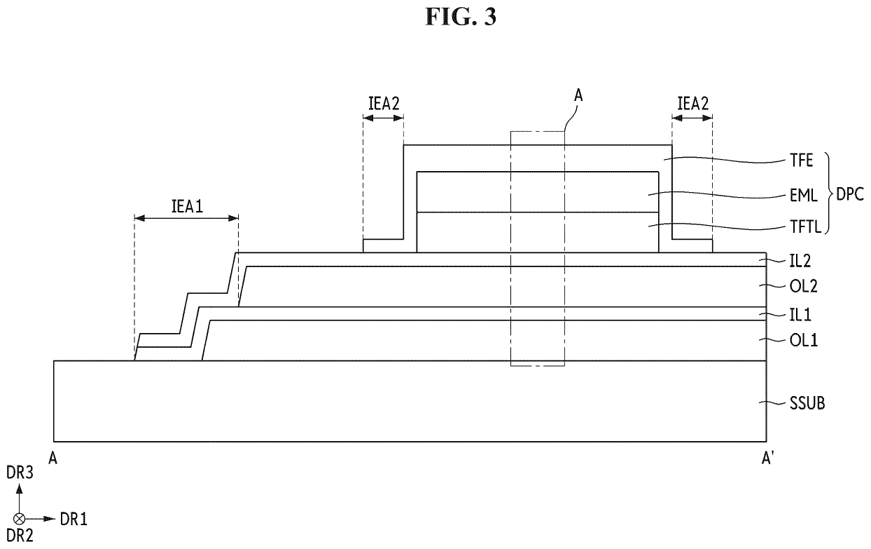

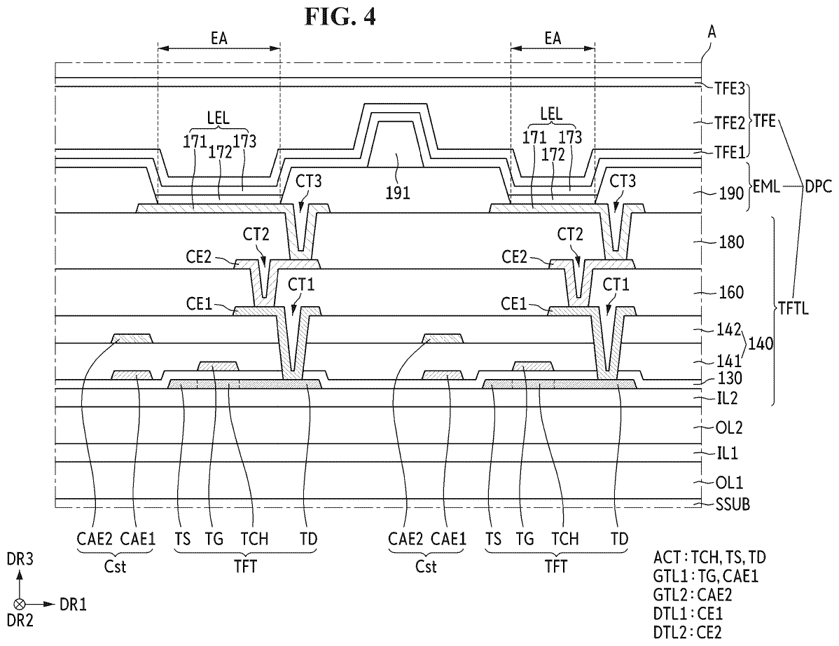

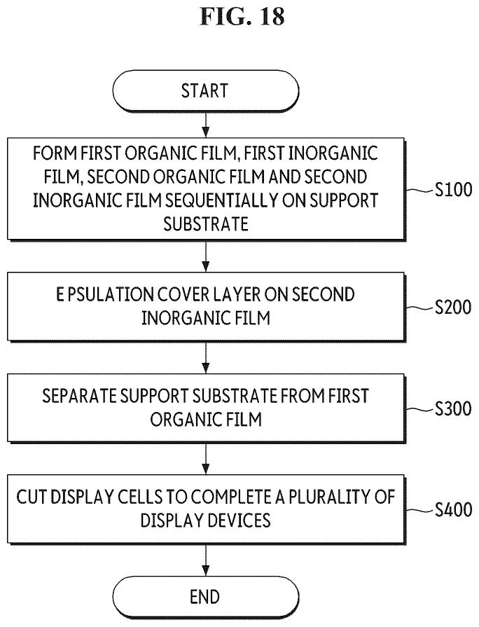

The plurality of display cells DPC may be concurrently (e.g., simultaneously) formed or arranged on the support substrate SSUB, and then may be cut by laser and/or a cutting unit in a cutting process, such that a plurality of display devices (or display panels) may be fabricated. The plurality of display cells DPC may be arranged in the first direction DR1 and the second direction DR2. The plurality of display cells DPC may be arranged in M rows and N columns, where M and N are positive integers. Although the display cells DPC are arranged in two rows and five columns in the example as shown in FIGS. 1 and 2, embodiments of the present disclosure are not limited thereto. The display cells DPC will be described in more detail herein with reference to FIGS. 3 and 4. In one or more embodiments, a method for fabricating a display device (or display panel) will be described in more detail herein with reference to FIG. 18.

The first inorganic encapsulation area IEA1 may be arranged along the edges of the support substrate SSUB. The first inorganic encapsulation area IEA1 may be around (e.g., surround) the display cells DPC. The second inorganic encapsulation area IEA2 may be around (e.g., surround) each of the display cells DPC. Each of the display cells DPC may be protected from moisture permeation by the first inorganic encapsulation area IEA1 and the second inorganic encapsulation area IEA2.

FIG. 3 is a cross-sectional view illustrating a support substrate, a first organic film, a first inorganic film, a second organic film, a second inorganic film, a first inorganic encapsulation area, and a display cell of the mother substrate taken along the line A-A′ of FIG. 2.

Referring to FIG. 3, the mother substrate MSUB according to one or more embodiments of the present disclosure may further include a first organic film OL1, a first inorganic film IL1, a second organic film OL2, and a second inorganic film IL2.

The first organic film OL1 may be arranged on the first surface of the support substrate SSUB. An edge of the first surface of the support substrate SSUB may be exposed without being covered by the first organic film OL1. A plurality of side surfaces of the support substrate SSUB may also be exposed without being covered by the first organic film OL1.

The first inorganic film IL1 may be arranged on the first organic film OL1. The first inorganic film IL1 may entirely cover the first organic film OL1. In one or more embodiments, the first inorganic film IL1 may cover the upper surface and side surfaces of the first organic film OL1. The first inorganic film IL1 may be arranged on a portion of the edge of the first surface of the support substrate SSUB that is exposed without being covered by the first organic film OL1. In one or more embodiments, another portion of the edge of the first surface of the support substrate SSUB may be exposed without being covered by the first inorganic film IL1.

The second organic film OL2 may be arranged on the first inorganic film IL1. An edge of the first inorganic film IL1 may be exposed without being covered by the second organic film OL2.

The second inorganic film IL2 may be arranged on the second organic film OL2. The second inorganic film IL2 may entirely cover the second organic film OL2. In one or more embodiments, the second inorganic film IL2 may cover the upper surface and side surfaces of the second organic film OL2.

The second inorganic film IL2 may be arranged on the first inorganic film IL1 that is exposed without being covered by the second organic film OL2. The second inorganic film IL2 may contact the first inorganic film IL1 that is exposed without being covered by the second organic film OL2. The area where the first inorganic film IL1 and the second inorganic film IL2 contact each other may be defined as the first inorganic encapsulation area IEA1.

If (e.g., when) the first organic film OL1 and the second organic film OL2 are exposed to the outside, they may be carbonized by laser in a laser process to crystalize an active layer of thin-film transistors of each of the display cells DPC from amorphous (e.g., non-crystalline) silicon (a-Si) to polycrystalline silicon (poly-Si). Because the first organic film OL1 and the second organic film OL2 are not exposed to the outside due to the first inorganic encapsulation area IEA1, it may be feasible to avoid the first organic film OL1 and the second organic film OL2 from being carbonized. Therefore, it may be feasible to prevent defects from occurring (or reduce a degree to or occurrence of which defects occur) due to particles caused by carbonization of the first organic film OL1 and the second organic film OL2. For example, if (e.g., when) the first organic film OL1 and the second organic film OL2 are exposed to the outside, they may be carbonized by laser during a process to crystallize an active layer of thin-film transistors in each of the display cells DPC from amorphous (e.g., non-crystalline) silicon (a-Si) to polycrystalline silicon (poly-Si). However, because the first organic film OL1 and the second organic film OL2 are not exposed to the outside due to the first inorganic encapsulation area IEA1, it may be feasible to avoid the carbonization of these films. This prevention of carbonization may help reduce or prevent defects that may occur due to particles formed from the carbonization of the first organic film OL1 and the second organic film OL2. Furthermore, the encapsulation provided by the first inorganic film and the second inorganic film may ensure that the organic films remain intact throughout the fabrication process, thereby enhancing the overall reliability and longevity of the display cells. This encapsulation method may not only protect the organic films from external environmental factors, such as moisture and/or oxygen but also contribute to the structural integrity of the display devices. As a result, the display devices may become more durable and efficient, making them suitable for a wide range of applications. This dual-layer encapsulation approach, particularly the first inorganic encapsulation area IEA1, may assist in maintaining or providing the performance and lifespan of the display cells, ensuring they function suitably or desirably in one or more environments. The first inorganic encapsulation area IEA1 may be formed or arranged by the contact between the first inorganic film IL1 and the second inorganic film IL2. For example, the first inorganic film IL1 may be arranged on the first organic film OL1, and the second inorganic film IL2 may be arranged on the second organic film OL2. The area where the first inorganic film IL1 and the second inorganic film IL2 contact each other may define the first inorganic encapsulation area IEA1. This interaction may enhance the structural integrity of the display cells by ensuring that the organic films remain intact and protected, contributing to the overall durability and efficiency of the display devices. Each of the first organic film OL1 and the second organic film OL2 may be of an organic material, such as an acryl resin, an epoxy resin, a phenolic resin, a polyamide resin, and/or a polyimide resin. The first organic film OL1 and the second organic film OL2 may be of either substantially the same organic material or different organic materials.

Each of the first inorganic film IL1 and the second inorganic film IL2 may be of an inorganic material, such as a silicon nitride layer, a silicon oxynitride layer, a silicon oxide layer, a titanium oxide layer, and/or an aluminum oxide layer. In one or more embodiments, each of the first inorganic film IL1 and the second inorganic film IL2 may be made up of multiple films in which inorganic layers selected from among a silicon nitride layer, a silicon oxynitride layer, a silicon oxide layer, a titanium oxide layer, and an aluminum oxide layer are alternately stacked on one another. The first inorganic film IL1 and the second inorganic film IL2 may be of either substantially the same organic material or different inorganic materials.

Each of the display cells DPC may include a thin-film transistor layer TFTL, a light emitting element layer EML, and an encapsulation layer TFE.

The thin-film transistor layer TFTL may include thin-film transistors. The thin-film transistor layer TFTL may be arranged on the second inorganic film IL2.

The light emitting element layer EML may include light-emitting elements. A plurality of light-emitting elements may be to emit light at a set or predetermined brightness by receiving a driving current or a driving voltage from the thin-film transistors. The light emitting element layer EML may be arranged on the thin-film transistor layer TFTL.

The encapsulation layer TFE may be arranged to be around (e.g., surround) the thin-film transistor layer TFTL and the light emitting element layer EML. The encapsulation layer TFE may include at least one inorganic film and at least one organic film. The at least one inorganic film may be arranged on a side surface of the thin-film transistor layer TFTL and upper and side surfaces of the light emitting element layer EML. The at least one organic film may be arranged on the upper surface of the light emitting element layer EML. Therefore, the thickness of the encapsulation layer TFE arranged on the side surfaces of the thin-film transistor layer TFTL and the side surfaces of the light emitting element layer EML may be smaller than the thickness of the encapsulation layer TFE arranged on the upper surface of the light emitting element layer EML.

The area where at least one inorganic film of the encapsulation layer TFE contacts the second inorganic film IL2 may be defined as the second inorganic encapsulation area IEA2. Because the second inorganic encapsulation area IEA2 is around (e.g., surrounds) each of the plurality of display cells DPC, each of the plurality of display cells DPC may be protected from moisture permeation by the second inorganic encapsulation area IEA2.

The thin-film transistor layer TFTL, the light emitting element layer EML, and the encapsulation layer TFE will be described in more detail herein with reference to FIG. 4.

FIG. 4 is a cross-sectional view illustrating area A of FIG. 3.

Referring to FIG. 4, each of the display cells DPC may include a thin-film transistor layer TFTL, a light emitting element layer EML, and an encapsulation layer TFE.

The thin-film transistor layer TFTL may include an active layer ACT, a first gate layer GTL1, a second gate layer GTL2, a first data metal layer DTL1, and a second data metal layer DTL2. In one or more embodiments, the thin-film transistor layer TFTL may include a buffer film BF, a gate insulator 130, a first interlayer dielectric film 141, a second interlayer dielectric film 142, a first planarization film 160, and a second planarization film 180. The thin-film transistor layer TFTL may include a plurality of thin-film transistors TFT. Each of the thin-film transistors may include a channel TCH, a gate electrode TG, a first electrode TS, and a second electrode TD.

The active layer ACT may be arranged on the second inorganic film IL2. The active layer ACT may include silicon semiconductor, such as polycrystalline silicon, monocrystalline silicon, and/or low-temperature polycrystalline silicon, and/or may include oxide semiconductor.

The active layer ACT may include a channel TCH, a first electrode TS, and a second electrode TD of each of the thin-film transistors TFT. The channel TCH may be a region that overlaps with the gate electrode TG of the thin-film transistor TFT in the 1 third direction DR3, which is the thickness direction of the substrate SUB. The first electrode TS may be arranged on one side of the channel TCH, and the second electrode TD may be arranged on the opposite side of the channel TCH. The first electrode TS and the second electrode TD may be regions that do not overlap with the gate electrode TG in the third direction DR3. The first electrode TS and the second electrode TD may be regions having conductivity (e.g., electrical conductivity) by doping ions in a silicon semiconductor and/or an oxide semiconductor.

The gate insulator 130 may be arranged on the active layer ACT. The gate insulator 130 may be of an inorganic layer, for example, a silicon nitride layer, a silicon oxynitride layer, a silicon oxide layer, a titanium oxide layer, and/or an aluminum oxide layer.

The first gate layer GTL1 may be arranged on the gate insulator 130. The first gate layer GTL1 may include the gate electrode TG of each of the thin-film transistors TFT and a first capacitor electrode CAE1. The first gate layer GTL1 may be made up of a single layer or multiple layers of one selected from among molybdenum (Mo), aluminum (AI), chromium (Cr), gold (Au), titanium (Ti), nickel (Ni), neodymium (Nd), and copper (Cu) or an (e.g., any suitable) alloy thereof.

The first interlayer dielectric film 141 may be arranged over the first gate layer GTL1. The first interlayer dielectric film 141 may be of an inorganic layer, for example, a silicon nitride layer, a silicon oxynitride layer, a silicon oxide layer, a titanium oxide layer, and/or an aluminum oxide layer.

The second gate line GTL2 may be arranged on the first interlayer dielectric film 141. The second gate layer GTL2 may include a second capacitor electrode CAE2. The second capacitor electrode CAE2 may overlap the first capacitor electrode CAE1 in the third direction DR3. The capacitor Cst may include a first capacitor electrode CAE1 and a second capacitor electrode CAE2. The second gate layer GTL2 may be made up of a single layer or multiple layers of one selected from among molybdenum (Mo), aluminum (AI), chromium (Cr), gold (Au), titanium (Ti), nickel (Ni), neodymium, (Nd) and copper (Cu) or an (any suitable) alloy thereof.

The second interlayer dielectric film 142 may be arranged over the second gate layer GTL2. The second interlayer dielectric film 142 may be of an inorganic layer, for example, a silicon nitride layer, a silicon oxynitride layer, a silicon oxide layer, a titanium oxide layer, and/or an aluminum oxide layer.

The first data metal layer DTL1 including a first connection electrode CE1 may be arranged on the second interlayer dielectric film 142. The first connection electrode CE1 may be connected to the first electrode TS or the second electrode TD of the thin-film transistor TFT through a first contact hole CT1 that penetrates the gate insulator 130, the first interlayer dielectric film 141, and the second interlayer dielectric film 142. The first data metal layer DTL1 may be made up of a single layer or multiple layers of one selected from among molybdenum (Mo), aluminum (AI), chromium (Cr), gold (Au), titanium (Ti), nickel (Ni), neodymium (Nd), and copper (Cu) or an (e.g., any suitable) alloy thereof.

The planarization film 160 may be arranged on the first data metal layer DTL to provide a flat surface (e.g., a substantially flat surface) over the level differences of the active layer ACT, the first gate layer GTL1, the second gate layer GTL2, and the first data metal layer DTL. The first planarization film 160 may be of an organic layer, such as an acryl resin, an epoxy resin, a phenolic resin, a polyamide resin, and/or a polyimide resin.

A second data metal layer DTL2 may be arranged on the first planarization film 160. The second data metal layer DTL2 may include a second connection electrode CE2. The second connection electrode CE2 may be connected to the first connection electrode CE1 through a second contact hole CT2 that penetrates the first planarization film 160. The second data metal layer DTL2 may be made up of a single layer or multiple layers of one selected from among molybdenum (Mo), aluminum (AI), chromium (Cr), gold (Au), titanium (Ti), nickel (Ni), neodymium (Nd), and copper (Cu) or an (e.g., any suitable) alloy thereof.

The second planarization film 180 may be arranged on the second data metal layer DTL2. The second planarization film 180 may be arranged as an organic layer, such as an acryl resin, an epoxy resin, a phenolic resin, a polyamide resin, and/or a polyimide resin.

A light emitting element layer EML may be arranged on the second planarization film 180. The light emitting element layer EML may include a plurality of light-emitting elements LEL and a bank 190. Each of the light-emitting elements LEL may be, but is not limited to, an organic light-emitting diode including a pixel electrode 171, an emissive layer 172, and a common electrode 173.

The pixel electrode 171 may be arranged on the second planarization film 180. The pixel electrode 171 may be connected to the second connection electrode CE2 through a third contact hole CT3 that penetrates the second planarization film 180.

In the top-emission structure in which light exits from the emissive layer 172 toward the common electrode 173, the pixel electrode 171 may be made of a metal material having a high reflectivity, such as a stack structure of aluminum and titanium (Ti/Al/Ti), a stack structure of aluminum and indium tin oxide (ITO) (ITO/AI/ITO), an APC alloy, and a stack structure of APC alloy and ITO (ITO/APC/ITO). The APC alloy may be an alloy of silver (Ag), palladium (Pd), and copper (Cu).

The pixel-defining layer 190 may be arranged on the second planarization film 180 to cover the edges of each of the pixel electrodes 171 in order to define the emission areas EA. The pixel-defining layer 190 may be of an organic layer, such as an acryl resin, an epoxy resin, a phenolic resin, a polyamide resin, and/or a polyimide resin.

In each of the emission areas EA, the pixel electrode 171, the emissive layer 172, and the common electrode 173 may be stacked on one another sequentially, so 1 that holes from the pixel electrode 171 and electrons from the common electrode 173 may be recombined in the emissive layer 172 to emit light.

The emissive layer 172 may be arranged on the pixel electrode 171. The emissive layer 172 may include an organic material to emit light of a certain color. For example, the emissive layer 172 may include a hole transporting layer, an organic material layer, and an electron transporting layer.

The common electrode 173 may be arranged on the emissive layer 172. The common electrode 173 may be arranged to cover the emissive layer 172. The common electrode 173 may be a common layer arranged across the emission areas EA. A capping layer may be arranged on the common electrode 173.

In the top-emission organic light-emitting diode, the common electrode 173 may be of a transparent (e.g., substantially transparent) conductive (e.g., electrically conductive) material (TCP), such as ITO and/or IZO that may transmit light, or a semi-transmissive conductive (e.g., electrically conductive) material, such as magnesium (Mg), silver (Ag), and/or an alloy of magnesium (Mg) and silver (Ag). If (e.g., when) the common electrode 173 is of a semi-transmissive metal material, the light extraction efficiency may be increased by using microcavities.

A spacer 191 may be arranged on the pixel-defining layer 190. The spacer 191 may be to support a mask during a process of fabricating the emissive layer 172. The spacer 191 may be of an organic layer, such as an acryl resin, an epoxy resin, a phenolic resin, a polyamide resin, and/or a polyimide resin.

The encapsulation layer TFE may be arranged on the common electrode 173. The encapsulation layer TFE may include at least one inorganic layer to prevent permeation of oxygen and/or moisture into the light-emitting element layer EML (or reduce a degree to or occurrence of which oxygen and/or moisture penetrates into the light-emitting element layer EML). In one or more embodiments, the encapsulation layer TFE may include at least one organic layer to protect the light-emitting element layer EML from foreign substances, such as dust. For example, the encapsulation layer TFEL may include a first inorganic encapsulation layer TFE1, an organic encapsulation layer TFE2, and a second inorganic encapsulation layer TFE3.

The first inorganic encapsulation layer TFE1 may be arranged on the common electrode 173, the organic encapsulation layer TFE2 may be arranged on the first inorganic encapsulation layer TFE1, and the second inorganic encapsulation layer TFE3 may be arranged on the organic encapsulation layer TFE2. The first inorganic encapsulation layer TFE1 and the second inorganic encapsulation layer TFE3 may be made up of multiple layers in which one or more inorganic layers selected from among a silicon nitride layer, a silicon oxynitride layer, a silicon oxide layer, a titanium oxide layer, and an aluminum oxide layer are alternately stacked on one another. The organic encapsulation layer TFE2 may be an organic film, such as an acryl resin, an epoxy resin, a phenolic resin, a polyamide resin, a polyimide resin, and/or the like.

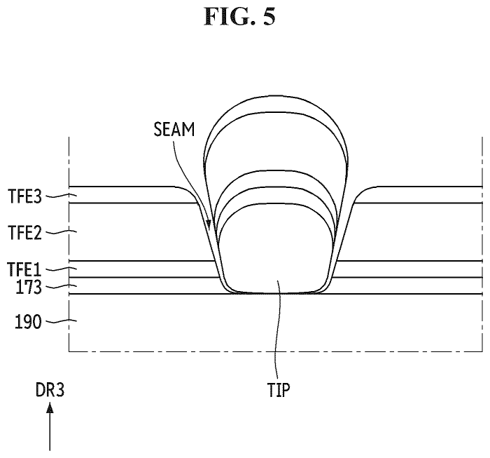

FIG. 5 is a cross-sectional view illustrating a seam that is formed if (e.g., when) a transparent inorganic particle in the first inorganic encapsulation area in FIG. 4 is placed on the encapsulation layer of a display cell.

Referring to FIG. 5, during the process of fabricating the display device, in order to prevent the first organic film OL1 and the second organic film OL2 from being carbonized (or reduce a degree to or occurrence of which the first organic film OL1 and the second organic film OL2 are carbonized) by laser in the laser process to crystalize the active layer of the thin-film transistors of each of the display cells DPC from amorphous (e.g., non-crystalline) silicon (a-Si) to polycrystalline silicon (poly-Si), the first inorganic encapsulation area IEA1 may be arranged where the first inorganic film IL1 and the second inorganic film IL2 contact each other. In one or more embodiments, because the adhesive strength between the first inorganic film IL1 and the second inorganic film IL2 in the first inorganic encapsulation area IEA1 is not high, if (e.g., when) the mother substrate MSUB physically contacts one or more mechanical parts of the equipment or a mask during the process of fabricating the display device and/or if (e.g., when) it is damaged by high-pressure spray of cleaning liquid during wet cleaning, transparent inorganic particles TIP may fall off from the first inorganic encapsulation area IEA1.

If (e.g., when) a transparent inorganic particle TIP is placed on the pixel-defining layer 190 as shown in FIG. 5, the common electrode 173, the first encapsulation inorganic film TFE1, the second encapsulation inorganic film TFE2, and the third encapsulation inorganic film TFE3 may be disconnected due to the height of the transparent inorganic particle TIP. For example, a seam SEAM may be formed in the encapsulation layer TFE, and moisture and/or oxygen may permeate through the seam SEAM, and thus the seam SEAM may become a path of moisture permeation. As a result, the light-emitting elements LEL may be oxidized by moisture and/or oxygen that penetrates through the seam SEAM. If (e.g., when) this happens, the light-emitting elements LEL may not be able to emit light. For this reason, it may be desired or necessary to prevent that a portion of the first inorganic encapsulation area IEA1 falls off (or reduce a degree to or occurrence of which a portion of the first inorganic encapsulation area IEA1 falls off) and transparent inorganic particles TIP are placed on the pixel-defining layer 190. For example, if (e.g., when) a transparent inorganic particle TIP is placed on the pixel-defining layer 190 as shown in FIG. 5, the common electrode 173, the first encapsulation inorganic film TFE1, the second encapsulation inorganic film TFE2, and the third encapsulation inorganic film TFE3 may be disconnected due to the height of the transparent inorganic particle TIP. For example, a seam SEAM may be formed in the encapsulation layer TFE, and moisture and/or oxygen may permeate through the seam SEAM, and thus the seam SEAM may become a path of moisture permeation. As a result, the light-emitting elements LEL may be oxidized by moisture and/or oxygen that penetrates through the seam SEAM. If (e.g., when) this happens, the light-emitting elements LEL may not be able to emit light. For this reason, it may be desirable to prevent or reduce the occurrence of a portion of the first inorganic encapsulation area IEA1 falling off and transparent inorganic particles TIP being placed on the pixel-defining layer 190.

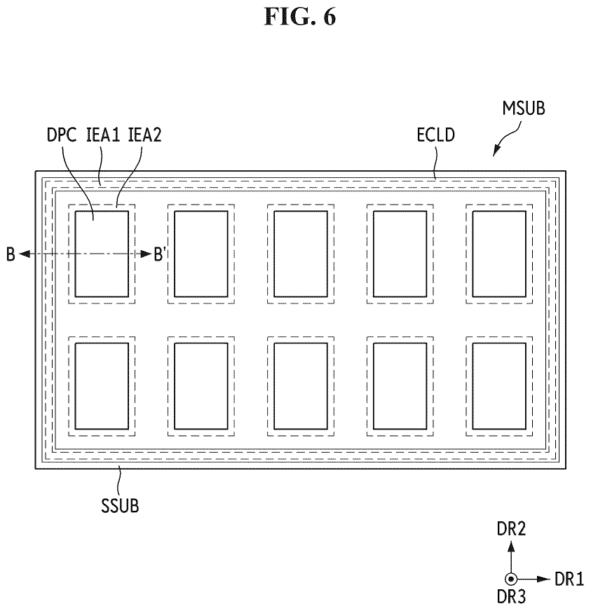

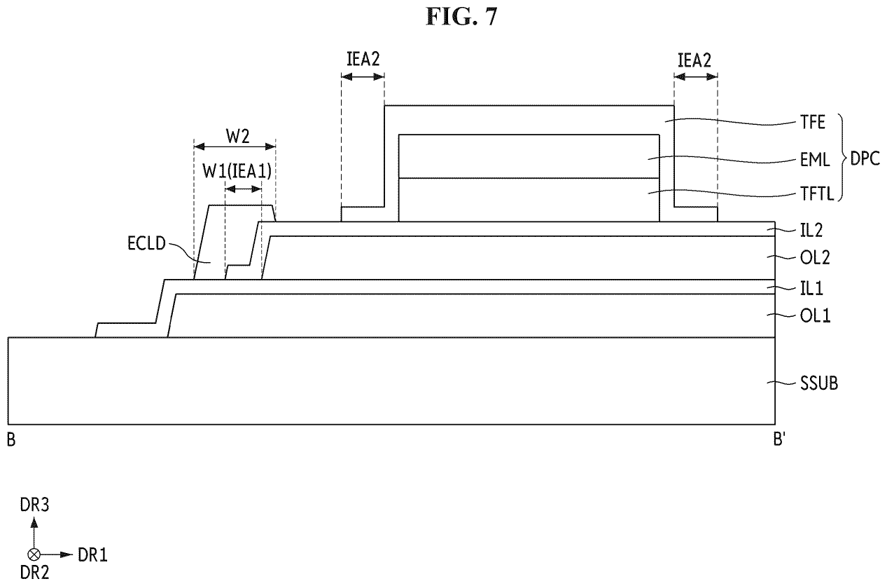

FIG. 6 is a layout diagram illustrating a support substrate, a plurality of display cells, a first inorganic encapsulation area, a second inorganic encapsulation area, and an encapsulation cover layer of the mother substrate of FIG. 1. FIG. 7 is a cross-sectional view illustrating a support substrate, a first organic film, a first inorganic film, a second organic film, a second inorganic film, a first inorganic encapsulation area, and a display cell of the mother substrate taken along the line B-B′ of FIG. 6. The following description will focus on differences, and the redundant descriptions may not be provided.

Referring to FIG. 6, the first inorganic encapsulation area IEA1 may be arranged along the edges of the support substrate SSUB. The first inorganic encapsulation area IEA1 may be around (e.g., surround) the display cells DPC. The second inorganic encapsulation area IEA2 may be around (e.g., surround) each of the display cells DPC.

An encapsulation cover layer ECLD may also be arranged along the edges of the support substrate SSUB. The width of the encapsulation cover layer ECLD may be greater than the width of the first inorganic encapsulation area IEA1. The first inorganic encapsulation area IEA1 may completely overlap with the encapsulation cover layer ECLD in the third direction DR3.

Referring to FIG. 7, the first inorganic encapsulation area IEA1 may be arranged on the inner side of the first organic film OL1. The second inorganic film IL2 included in the first inorganic encapsulation area IEA1 may overlap with the first organic film OL1 and the first inorganic film IL1 in the third direction DR3. In the example as shown in FIG. 3, the first inorganic encapsulation area IEA1 where the second inorganic film IL2 and the first inorganic film IL1 contact each other may be extended to the outside of the edge of the first organic film OL1. In contrast, in the example as shown in FIG. 7, the first inorganic encapsulation area IEA1 where the second inorganic film IL2 and the first inorganic film IL1 contact each other may be reduced inside the edge of the first organic film OL1, and accordingly the first organic 1 encapsulation area IEA1 may be spaced and/or apart (e.g., spaced apart or separated) from the support substrate SSUB.

The encapsulation cover layer ECLD may cover the first inorganic encapsulation area IEA1. The width W2 of the encapsulation cover layer ECLD may be greater than the width W1 of the first inorganic encapsulation area IEA1. The encapsulation cover layer ECLD may be around (e.g., surround) a plurality of display cells DPC.

The encapsulation cover layer ECLD may be arranged on the first inorganic film IL1 and the second inorganic film IL2. The encapsulation cover layer ECLD may be arranged on the upper surface of the first inorganic film IL1 and the upper surface and side surface of the second inorganic film IL2. The encapsulation cover layer ECLD may not be arranged on the side surface of the first inorganic film IL1 or the support substrate SSUB that is exposed without being covered by the first inorganic film IL1.

The encapsulation cover layer ECLD may not cover the edge of the first organic film OL1. The encapsulation cover layer ECLD may overlap the edge of the second organic film OL2 in the third direction DR3 (e.g., in the thickness direction of the support substrate SSUB). In one or more embodiments, the encapsulation cover layer ECLD may overlap the first organic film OL1 in the third direction DR3.

The encapsulation cover layer ECLD may be of an organic material, such as an acryl resin, an epoxy resin, a phenolic resin, a polyamide resin, and/or a polyimide resin. In one or more embodiments, the encapsulation cover layer ECLD may be of substantially the same organic material as one selected from among the first planarization film 160, the second planarization film 180, the pixel-defining layer 190, and the spacer 191. The encapsulation cover layer ECLD1 may include an organic material having lower heat resistance than the first organic film OL1. In one or more embodiments, the thickness of the encapsulation cover layer ECLD may be greater than the thickness of the first inorganic film IL1 and the thickness of the second inorganic film IL2.

Because the adhesive strength between the first inorganic film IL1 and the second inorganic film IL2 in the first inorganic encapsulation area IEA1 is not high, by covering the first inorganic encapsulation area IEA1 with the encapsulation cover layer ECLD, it may be feasible to prevent the first inorganic encapsulation area IEA1 from being damaged (or reduce a degree to or occurrence of which the first inorganic encapsulation area IEA1 is damaged) by physical contact with the fabrication equipment and high-pressure spray of a cleaning liquid from the cleaning equipment during the fabrication process. As a result, it may be feasible to prevent parts of the first inorganic film IL1 and the second inorganic film IL2 in the first inorganic encapsulation area IEA1 from falling off (or reduce a degree to or occurrence of which parts of the first inorganic film IL1 and the second inorganic film IL2 in the first inorganic encapsulation area IEA1 fall off). For example, because the adhesive strength between the first inorganic film IL1 and the second inorganic film IL2 in the first inorganic encapsulation area IEA1 is not high, covering the first inorganic encapsulation area IEA1 with the encapsulation cover layer ECLD can help prevent or reduce damage to the first inorganic encapsulation area IEA1 caused by physical contact with fabrication equipment and high-pressure spray of cleaning liquid during the fabrication process. As a result, it may be feasible to prevent or reduce the occurrence of parts of the first inorganic film IL1 and the second inorganic film IL2 in the first inorganic encapsulation area IEA1 falling off. This additional protection provided by the encapsulation cover layer ECLD ensures that the integrity of the encapsulation is maintained, thereby preventing transparent inorganic particles TIP from being placed on the pixel-defining layer 190. This is desirable for maintaining the performance and longevity of the display cells DPC, as it prevents or reduces moisture and/or oxygen from penetrating through seams formed by dislodged particles, which may otherwise lead to oxidation and failure of the light-emitting elements LEL.

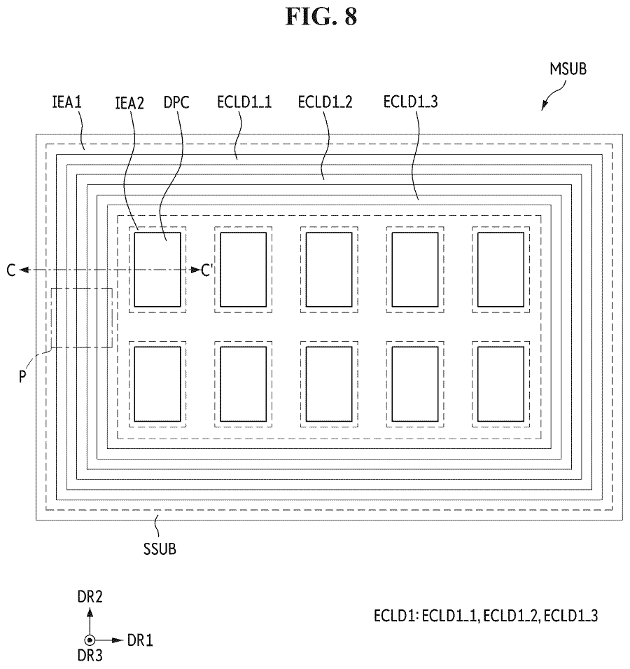

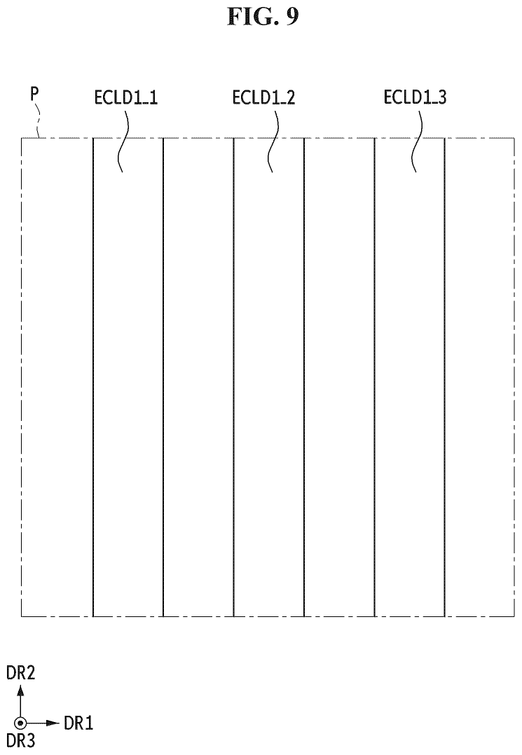

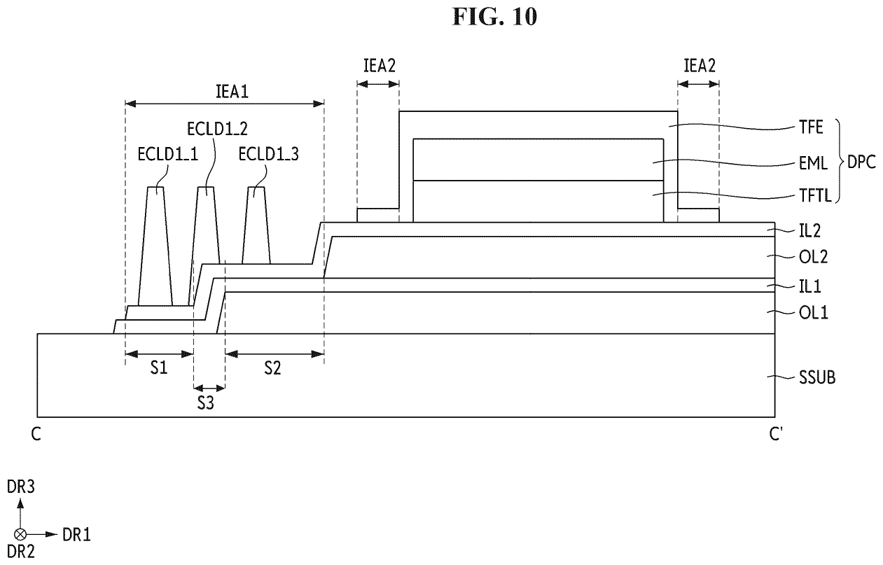

FIG. 8 is a layout diagram illustrating a support substrate, a plurality of display cells, a first inorganic encapsulation area, a second inorganic encapsulation area, and an encapsulation cover layer of the mother substrate of FIG. 1. FIG. 9 is a layout diagram illustrating area P of FIG. 8 in more detail. FIG. 10 is a cross-sectional view illustrating a support substrate, a first organic film, a first inorganic film, a second organic film, a second inorganic film, a first inorganic encapsulation area, and a display cell of the mother substrate taken along the line C-C′ of FIG. 8.

FIGS. 8 to 10 are substantially identical to FIG. 7 except that FIGS. 8 to 10 include a plurality of encapsulation cover layers and, therefore, the redundant descriptions may not be provided.

Referring to FIGS. 8 and 9, the encapsulation cover layer ECLD1 may include a plurality of encapsulation cover layers. The plurality of encapsulation cover layers ECLD1 may also be arranged along the edges of the support substrate SSUB. The encapsulation cover layers ECLD1 may be arranged on the first inorganic encapsulation area IEA1.

The plurality of encapsulation cover layers may include a first encapsulation cover layer ECLD1_1, a second encapsulation cover layer ECLD1_2, and a third encapsulation cover layer ECLD1_3. The first encapsulation cover layer ECLD1_1, the second encapsulation cover layer ECLD1_2, and the third encapsulation cover layer ECLD1_3 may be spaced and/or apart (e.g., spaced apart or separated) from one another.

Each of the first encapsulation cover layer ECLD1_1, the second encapsulation cover layer ECLD1_2, and the third encapsulation cover layer ECLD1_3 may have a shape of a rectangular frame (e.g., a substantially rectangular frame) if (e.g., when) viewed from the top. The first encapsulation cover layer ECLD1_1 may be arranged at the outermost position.

The second encapsulation cover layer ECLD1_2 may be arranged on the inner side of the first encapsulation cover layer ECLD1_1. The second encapsulation cover layer ECLD1_2 may be arranged closer to the plurality of display cells DPC than the first encapsulation cover layer ECLD1_1. The area of the second encapsulation cover layer ECLD1_2 may be smaller than the area of the first encapsulation cover layer ECLD1_1 if (e.g., when) viewed from the top.

The third encapsulation cover layer ECLD1_3 may be arranged on the inner side of the second encapsulation cover layer ECLD1_2. The third encapsulation cover layer ECLD1_3 may be arranged closer to the plurality of display cells DPC than the second encapsulation cover layer ECLD1_2. The area of the third encapsulation cover layer ECLD1_3 may be smaller than the area of the second encapsulation cover layer ECLD1_2 if (e.g., when) viewed from the top.

Referring to FIG. 10, the first inorganic encapsulation area IEA1 may include a first region S1 that contacts the support substrate SSUB and is flat (e.g., substantially flat), a second region S2 that contacts the first organic film OL1 and is flat (e.g., substantially flat), and a third region S3 between the first region S1 and the second region S2. In the third region S3, a set or predetermined slope may be formed or provided.

The first encapsulation cover layer ECLD1_1, the second encapsulation cover layer ECLD1_2, and the third encapsulation cover layer ECLD1_3 may be arranged on the inner side of the edge of the first inorganic film IL1. In one or more embodiments, the first encapsulation cover layer ECLD1_1, the second encapsulation cover layer ECLD1_2, and the third encapsulation cover layer ECLD1_3 may be arranged on the inner side of the edge of the second inorganic film IL2.

The first encapsulation cover layer ECLD1_1 may be arranged in the first region S1 of the first inorganic encapsulation area IEA1. The first encapsulation cover layer ECLD1_1 may be arranged on the second inorganic film IL2. The first encapsulation cover layer ECLD1_1 may be arranged outside the edge of the first organic film OL1.

The second encapsulation cover layer ECLD1_2 may be arranged in the third region S3 of the first inorganic encapsulation area IEA1. The second encapsulation cover layer ECLD1_2 may be arranged on the second inorganic film IL2. The second encapsulation cover layer ECLD1_2 may overlap with the edge of the first organic film OL1 in the third direction DR3 (e.g., in the thickness direction of the support substrate SSUB). For example, the second encapsulation cover layer ECLD1_2 may be arranged on the inclined portions of the first organic film OL1 and the second inorganic film IL2.

The third encapsulation cover layer ECLD1_3 may be arranged in the second region S2 of the first inorganic encapsulation area IEA1. The third encapsulation cover layer ECLD1_3 may be arranged on the second inorganic film IL2. The third encapsulation cover layer ECLD1_3 may be arranged on the inner side of the edge of the first organic film OL1.

The first encapsulation cover layer ECLD1_1, the second encapsulation cover layer ECLD1_2, and the third encapsulation cover layer ECLD1_3 may have a shape of a rectangular frame (e.g., a substantially rectangular frame) if (e.g., when) viewed from the top. The first encapsulation cover layer ECLD1_1, the second encapsulation cover layer ECLD1_2, and the third encapsulation cover layer ECLD1_3 may have substantially the same width.

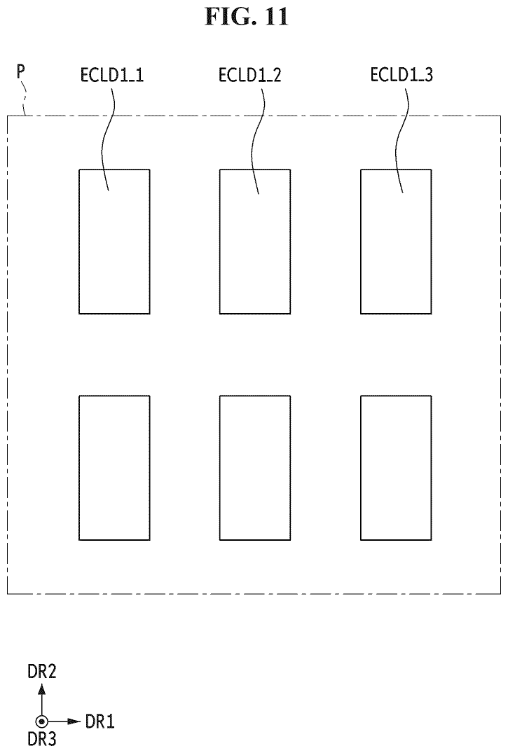

FIG. 11 is a layout diagram illustrating area P of FIG. 8 in more detail.

FIG. 11 is substantially identical to FIG. 9 except for the shapes of the first encapsulation cover layer ECLD1_1, the second encapsulation cover layer ECLD1_2, and the third encapsulation cover layer ECLD1_3 and, therefore, the redundant descriptions may not be provided.

Referring to FIG. 11, the first encapsulation cover layers ECLD1_1 may be spaced and/or apart (e.g., spaced apart or separated) from one another in the second direction DR2. The first encapsulation cover layers ECLD1_1 may be substantially equally spaced and/or apart (e.g., spaced apart or separated) from one another.

The second encapsulation cover layers ECLD1_2 may be spaced and/or apart (e.g., spaced apart or separated) from one another in the second direction DR2. The second encapsulation cover layers ECLD1_2 may be substantially equally spaced and/or apart (e.g., spaced apart or separated) from one another. The distance between the first encapsulation cover layers ECLD1_1 adjacent to each other in the second direction DR2 may be substantially equal to the distance between the second encapsulation cover layers ECLD1_2 adjacent to each other in the second direction DR2.

The third encapsulation cover layers ECLD1_3 may be spaced and/or apart (e.g., spaced apart or separated) from one another in the second direction DR2. The third encapsulation cover layers ECLD1_3 may be substantially equally spaced and/or apart (e.g., spaced apart or separated) from one another. The distance between the third encapsulation cover layers ECLD1_3 adjacent to each other in the second direction DR2 may be substantially equal to the distance between the second encapsulation cover layers ECLD1_2 adjacent to each other in the second direction DR2.

The first encapsulation cover layers ECLD1_1, the second encapsulation cover layers ECLD1_2, and the third encapsulation cover layers ECLD1_3 may be spaced and/or apart (e.g., spaced apart or separated) from one another in the first direction DR1. One selected from among the first encapsulation cover layers ECLD1_1, one selected from among the second encapsulation cover layers ECLD1_2 and one selected from among the third encapsulation cover layers ECLD1_3 may be aligned in the first direction DR1.

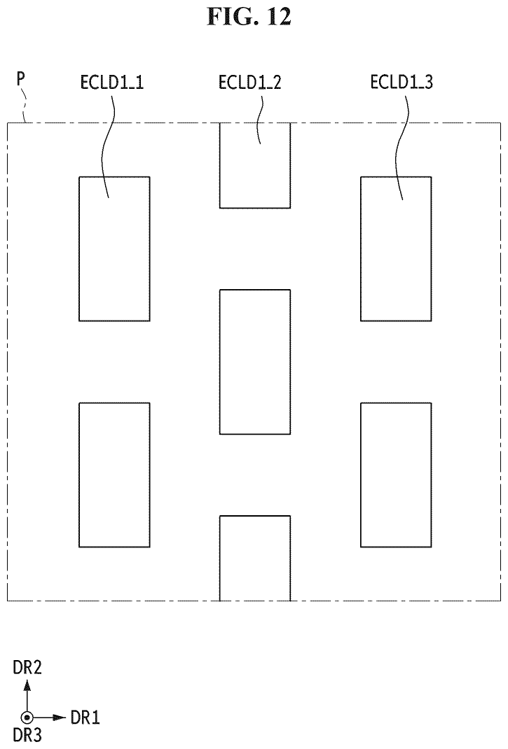

FIG. 12 is a layout diagram illustrating area P of FIG. 8 in more detail.

FIG. 12 is substantially identical to FIGS. 9 and 11 except for a specific shape of the first encapsulation cover layer ECLD1_1, the second encapsulation cover layer ECLD1_2, and the third encapsulation cover layer ECLD1_3 and, therefore, the redundant descriptions may not be provided.

Referring to FIG. 12, the first encapsulation cover layer ECLD1_1, the second encapsulation cover layer ECLD1_2, and the third encapsulation cover layer ECLD1_3 may be arranged in a staggered pattern. At least one selected from among the first encapsulation cover layer ECLD1_1, the second encapsulation cover layer ECLD1_2, and the third encapsulation cover layer ECLD1_3 may not be aligned in the first direction DR1.

A portion of the first encapsulation cover layer ECLD1_1, a portion of the second encapsulation cover layer ECLD1_2, and a portion of the third encapsulation cover layer ECLD1_3 may overlap one another in the first direction DR1. The portion of the first encapsulation cover layer ECLD1_1 may be an edge of the first encapsulation cover layer ECLD1_1 in the second direction DR2, e.g., the upper edge. The portion of the second encapsulation cover layer ECLD1_2 may be an edge of the second encapsulation cover layer ECLD1_in the second direction DR2, e.g., the lower edge. The portion of the third encapsulation cover layer ECLD1_3 may be an edge of the third encapsulation cover layer ECLD1_3 in the second direction DR2, e.g., the upper edge.

Although the portion of the first encapsulation cover layer ECLD1_1, the portion of the second encapsulation cover layer ECLD1_2, and the portion of the third encapsulation cover layer ECLD1_3 may overlap one another in the first direction DR1 in the example as shown in FIG. 12, embodiments of the present disclosure are not limited thereto. Each of the first encapsulation cover layer ECLD1_1 and the third encapsulation cover layer ECLD1_3 may not overlap with the second encapsulation cover layer ECLD1_2 in the first direction DR1.

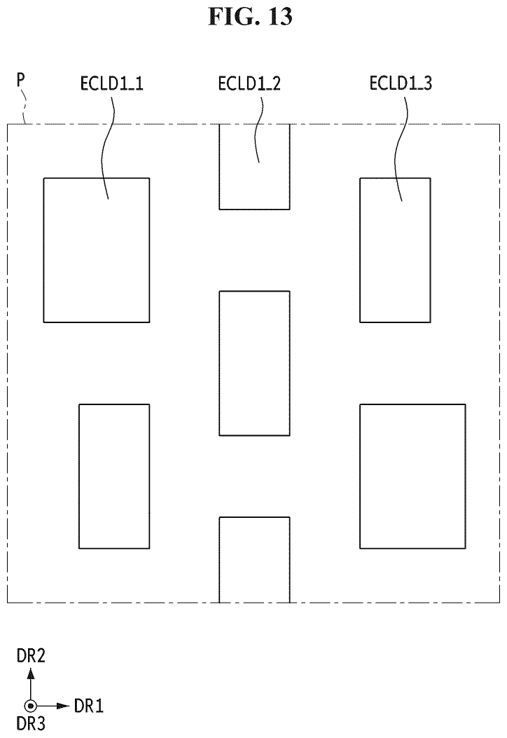

FIG. 13 is a layout diagram illustrating area P of FIG. 8 in more detail.

FIG. 13 is substantially identical to FIGS. 9, 11, and 12 except for a specific shape of the first encapsulation cover layer ECLD1_1, the second encapsulation cover layer ECLD1_2, and the third encapsulation cover layer ECLD1_3 and, therefore, the redundant descriptions may not be provided.

Referring to FIG. 13, the width of one or more of the first encapsulation cover layers ECLD1_1 and the third encapsulation cover layers ECLD1_3 in the first direction DR1 may increase. A first encapsulation cover layer ECLD1_1 with the increased 1 width in the first direction DR1 may be aligned with a third encapsulation cover layer ECLD1_3 with the width not increased in the first direction DR1, and a first end cover layer ECLD1_1 with the width not increased in the first direction DR1 may be aligned with the third encapsulation cover layer ECLD1_3 with the increased width in the first direction DR1.

Although the width of the second encapsulation cover layers ECLD1_2 is constant in the example as shown in FIG. 13, embodiments of the present disclosure are not limited thereto. The width of one or more of the second encapsulation cover layers ECLD1_2 in the first direction DR1 may also be increased or decreased.

In one or more embodiments, the second encapsulation cover layers ECLD1_2 may not be aligned with the first encapsulation cover layers ECLD1_1 or the third encapsulation cover layers ECLD1_3 in the first direction DR1. It should be understood, however, that embodiments of the present disclosure are not limited thereto. The shapes of the first encapsulation cover layer ECLD1_1, the second encapsulation cover layer ECLD1_2, and the third encapsulation cover layer ECLD1_3 may be modified and implemented in one or more suitable ways. For example, the width of one or more of the first encapsulation cover layer ECLD1_1, the second encapsulation cover layer ECLD1_2, and the third encapsulation cover layer ECLD1_3 in the second direction DR2 may be increased or decreased.

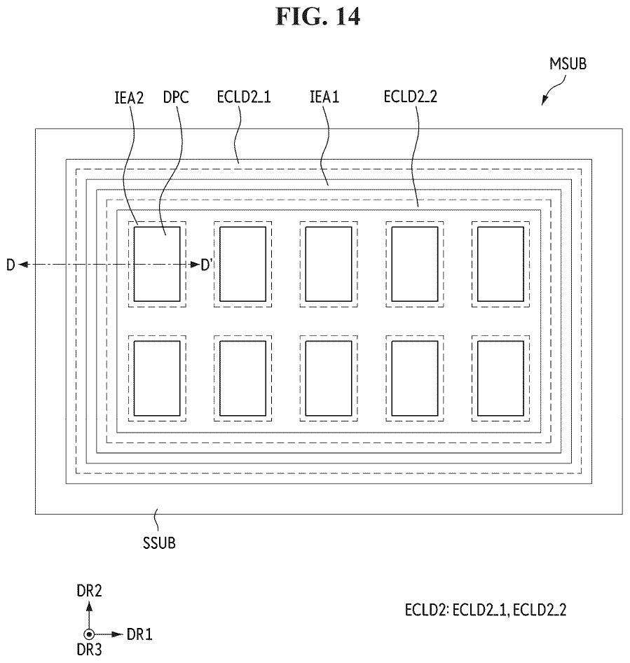

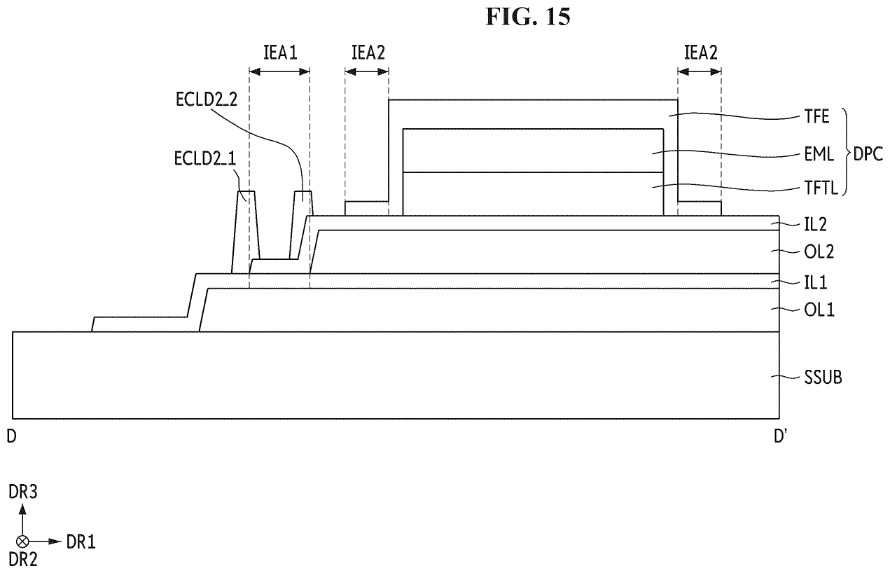

FIG. 14 is a layout diagram illustrating a support substrate, a plurality of display cells, a first inorganic encapsulation area, a second inorganic encapsulation area, and an encapsulation cover layer of the mother substrate of FIG. 1. FIG. 15 is a cross-sectional view illustrating a support substrate, a first organic film, a first inorganic film, a second organic film, a second inorganic film, a first inorganic encapsulation area, and a display cell of the mother substrate taken along the line D-D′ of FIG. 14. The following description will focus on differences, and the redundant descriptions may not be provided.

Referring to FIG. 14, an encapsulation cover layer ECLD2 may include a first encapsulation cover layer ECLD2_1 and a second encapsulation cover layer ECLD2_2 that are spaced and/or apart (e.g., spaced apart or separated) from each other. The first encapsulation cover layer ECLD2_1 and the second encapsulation cover layer ECLD2_2 may have a shape of a rectangular frame (e.g., a substantially rectangular frame) if (e.g., when) viewed from the top. The first encapsulation cover layer ECLD2_1 may be arranged at the outermost position.

The second encapsulation cover layer ECLD2_2 may be arranged on the inner side of the first encapsulation cover layer ECLD2_1. The second encapsulation cover layer ECLD2_2 may be arranged closer to the plurality of display cells DPC than the first encapsulation cover layer ECLD2_1.

The width of the first inorganic encapsulation area IEA1 may be greater than the width of the first encapsulation cover layer ECLD2_1 and the width of the second encapsulation cover layer ECLD2_2.

Each of the first encapsulation cover layer ECLD2_1 and the second encapsulation cover layer ECLD2_2 may overlap with the first inorganic encapsulation area IEA1. The area where the first encapsulation cover layer ECLD2_1 overlaps with the first inorganic encapsulation area IEA1 may be different from the area where the second encapsulation cover layer ECLD2_2 overlaps with the first inorganic encapsulation area IEA1.

Referring to FIG. 15, the first encapsulation cover layer ECLD2_1 may be in line with the outer edge of the first inorganic encapsulation area IEA1 in the third direction DR3. The second encapsulation cover layer ECLD2_2 may be in line with the inner edge of the first inorganic encapsulation area IEA1 in the third direction DR3.

The first encapsulation cover layer ECLD2_1 may be arranged on the first inorganic film IL1 and the second inorganic film IL2. The first encapsulation cover layer ECLD2_1 may not overlap with the second organic film OL2 in the third direction DR3. The first encapsulation cover layer ECLD2_1 may cover an edge of the second inorganic film IL2.

The second encapsulation cover layer ECLD2_2 may be arranged on the second inorganic film IL2. The second encapsulation cover layer ECLD2_2 may overlap with an edge of the second organic film OL2 in the third direction DR3. In one or more embodiments, the second encapsulation cover layer ECLD2_2 may cover the inclined portion of the second inorganic film IL2.

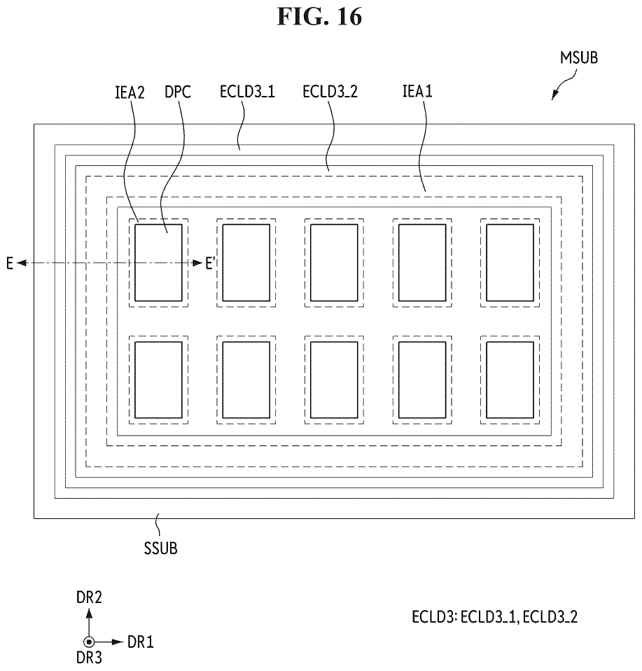

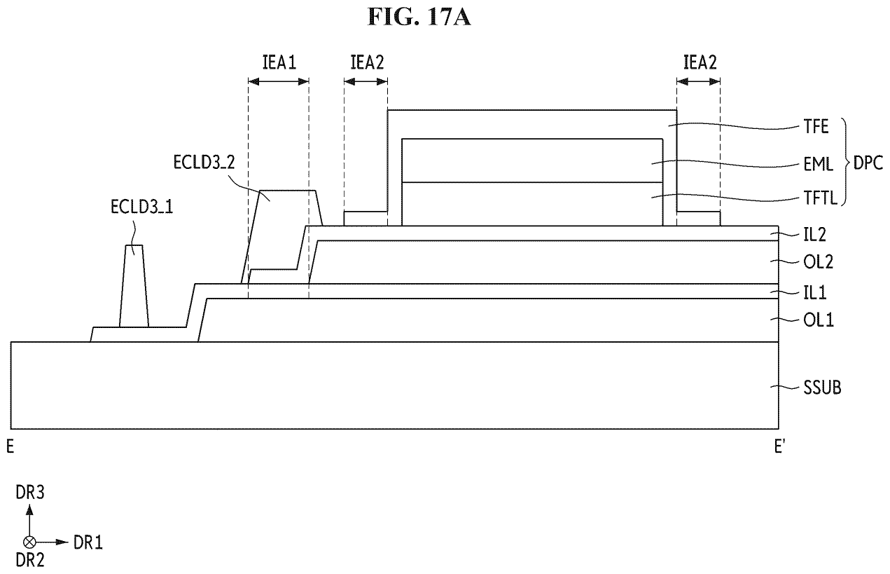

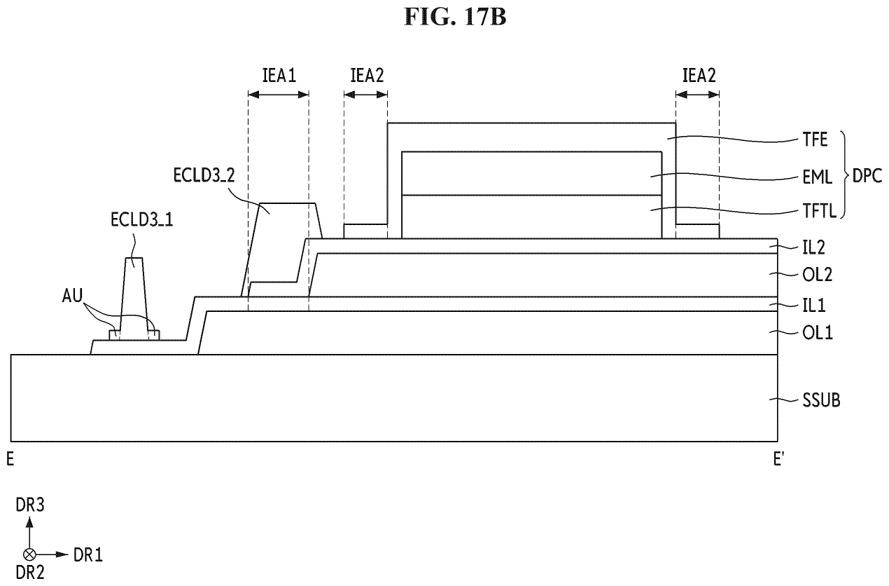

FIG. 16 is a layout diagram illustrating a support substrate, a plurality of display cells, a first inorganic encapsulation area, a second inorganic encapsulation area, and an encapsulation cover layer of the mother substrate of FIG. 1. FIGS. 17A and 17B are cross-sectional views each illustrating a support substrate, a first organic film, a first inorganic film, a second organic film, a second inorganic film, a first inorganic encapsulation area, and a display cell of the mother substrate taken along the line E-E′ of FIG. 16. The following description will focus on differences, and the redundant descriptions may not be provided.

Referring to FIG. 16, an encapsulation cover layer ECLD3 may include a first encapsulation cover layer ECLD3_1 and a second encapsulation cover layer ECLD3_2 that are spaced and/or apart (e.g., spaced apart or separated) from each other.

The first encapsulation cover layer ECLD3_1, the second encapsulation cover layer ECLD3_2, and the first inorganic encapsulation area IEA1 may be arranged along the edges of the support substrate SSUB.

The first encapsulation cover layer ECLD3_1 may be arranged outside the first inorganic encapsulation area IEA1. The second encapsulation cover layer ECLD3_2 may overlap with the first inorganic encapsulation area IEA1 in the third direction DR3.

The width of the second encapsulation cover layer ECLD3_2 may be greater than the width of the first inorganic encapsulation area IEA1.

Referring to FIG. 17A, the first encapsulation cover layer ECLD3_1 may be arranged on the first inorganic film IL1. The first encapsulation cover layer ECLD3_1 may be arranged outside the edge of the first organic film OL1. In one or more embodiments, the first encapsulation cover layer ECLD3_1 may not overlap with the first organic film OL1 in the third direction DR3.

The second encapsulation cover layer ECLD3_2 may be arranged on the first inorganic film IL1 and the second inorganic film IL2. The second encapsulation cover layer ECLD3_2 may overlap with the first organic film OL1 in the third direction DR3. The second encapsulation cover layer ECLD3_2 may overlap with the edge of the second organic film OL2. In one or more embodiments, the second encapsulation cover layer ECLD3_2 may cover the inclined portion of the second inorganic film IL2 on the second organic film OL2. In one or more embodiments, the second encapsulation cover layer ECLD3_2 may cover the edge of the second inorganic film IL2. Accordingly, the second encapsulation cover layer ECLD3_2 may cover the first inorganic encapsulation area IEA1.

In one or more embodiments, the first encapsulation cover layer ECLD3_1 may be arranged on the first inorganic film IL1 outside the edge of the first organic film OL1. Accordingly, it may be feasible to prevent a mask from contacting the first inorganic film IL1 (or reduce a degree to or occurrence of which a mask contacts the first inorganic film IL1) during the process of fabricating the display device, thereby preventing the first inorganic film IL1 from falling off (or reducing a degree to or occurrence of which the first inorganic film IL1 falls off). For example, the first encapsulation cover layer ECLD3_1 may protect the single layer of the first inorganic film IL1.

In contrast, the second encapsulation cover layer ECLD3_2 may protect the area where the first inorganic film IL1 and the second inorganic film IL2 contact each other, as described in one or more embodiments with reference to FIG. 7.

Referring to FIG. 17B, at least one selected from among the first encapsulation cover layer ECLD3_1 and the second encapsulation cover layer ECLD3_1 may include an auxiliary portion AU to increase bonding strength with the second inorganic film IL2. Although the first encapsulation cover layer ECLD3_1 includes the auxiliary portion AU in the example as shown in FIG. 17B, embodiments of the present disclosure are not limited thereto.

The auxiliary portion AU may protrude from the lower portion of the first encapsulation cover layer ECLD3_1. The auxiliary portion AU may be arranged on the inner side and the outer side of the first encapsulation cover layer ECLD3_1. For example, if (e.g., when) the first encapsulation cover layer ECLD3_1 is extended in the second direction DR2, the auxiliary portion AU may protrude from the first encapsulation cover layer ECLD3_1 in the first direction DR1 or in the opposite direction to the first direction DR1.

By virtue of the auxiliary portion AU, the contact area between the first encapsulation cover layer ECLD3_1 and the second inorganic film IL2 may increase.

For example, referring to FIG. 14, the encapsulation cover layer ECLD2 may be composed of two parts: the first encapsulation cover layer ECLD2_1 and the second encapsulation cover layer ECLD2_2, which are spaced and/or apart (e.g., spaced apart or separated) from each other. The first encapsulation cover layer ECLD2_1 may be positioned or arranged at the outermost edge, while the second encapsulation cover layer ECLD2_2 may be closer to the display cells DPC. The width of the first inorganic encapsulation area IEA1 may be greater than the widths of both (e.g., simultaneously) encapsulation cover layers. Each encapsulation cover layer may overlap with different areas of the first inorganic encapsulation area IEA1. In FIG. 15, the first encapsulation cover layer ECLD2_1 may align with the outer edge of IEA1, and the second encapsulation cover layer ECLD2_2 may align with the inner edge of IEA1. The first encapsulation cover layer ECLD2_1 may cover the edge of the second inorganic film IL2, while the second encapsulation cover layer ECLD2_2 may overlap with the edge of the second organic film OL2. In FIG. 16, the encapsulation cover layer ECLD3 may also be composed of two parts: ECLD3_1 and ECLD3_2. The first encapsulation cover layer ECLD3_1 may be arranged outside the first inorganic encapsulation area IEA1, while the second encapsulation cover layer ECLD3_2 may overlap with IEA1. The width of ECLD3_2 may be greater than that of IEA1. In FIG. 17A, ECLD3_1 may be positioned or arranged on the first inorganic film IL1 outside the edge of the first organic film OL1, preventing contact with the first inorganic film IL1 during fabrication. ECLD3_2, on the other hand, may cover the area where IL1 and IL2 contact each other, protecting this critical area. FIG. 17B shows that the encapsulation cover layers may include an auxiliary portion AU to increase bonding strength with IL2,

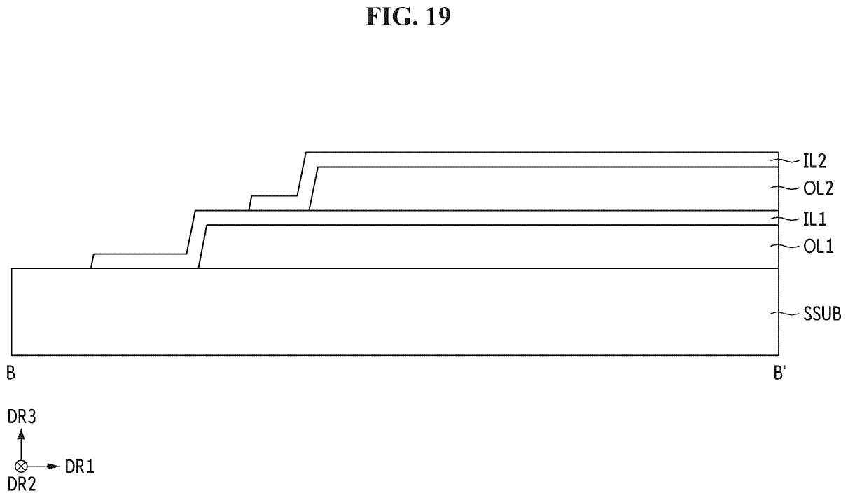

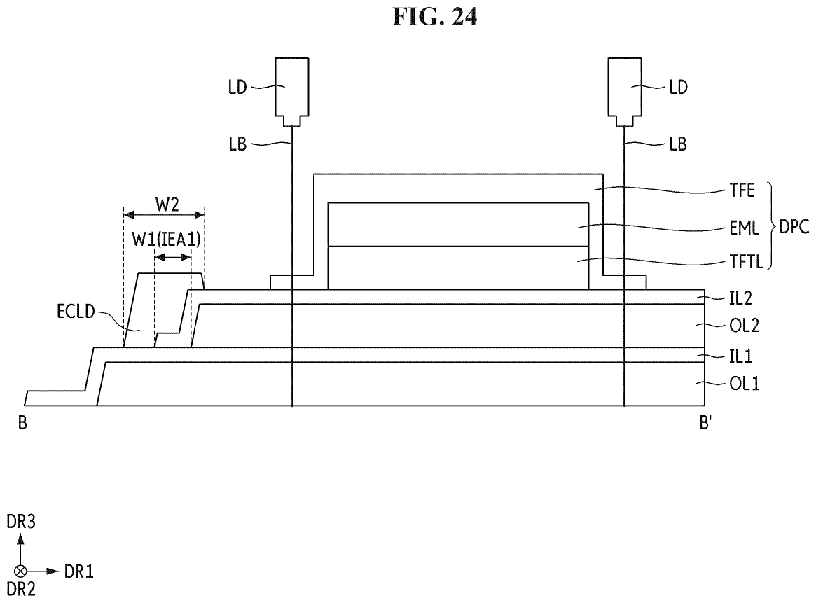

FIG. 18 is a flowchart illustrating a method for fabricating a mother substrate including a plurality of display cells according to one or more embodiments of the present disclosure. FIGS. 19 to 24 are views illustrating a method for fabricating a mother substrate that includes a plurality of display cells according to one or more embodiments of the present disclosure. The following description will focus on differences, and the redundant descriptions may not be provided.

Initially, a first organic film OL1, a first inorganic film IL1, a second organic film OL2, and a second inorganic film IL2 may be sequentially arranged on a support substrate SSUB (step (e.g., act or task) S100 of FIG. 18).

Referring to FIG. 19, the first organic film OL1 may be arranged on the support substrate SSUB. An edge of the first organic film OL1 may be arranged on the support substrate SSUB.

The first inorganic film IL1 may be arranged on the first organic film OL1 to cover the edge of the first organic film OL1. An edge of the first inorganic film IL1 may be arranged on the support substrate SSUB.

The second organic film OL2 may be arranged on the first inorganic film IL1. An edge of the second organic film OL2 may be arranged on the first inorganic film IL1.

The second inorganic film IL2 may be arranged on the second organic film OL2 to cover the edge of the second inorganic film IL2. An edge of the second inorganic film IL2 may be arranged on the first inorganic film IL1.

Subsequently, a plurality of display cells DPC and an encapsulation cover layer ECLD may be arranged on the second inorganic film IL2 (step (e.g., act or task) S200 of FIG. 18).

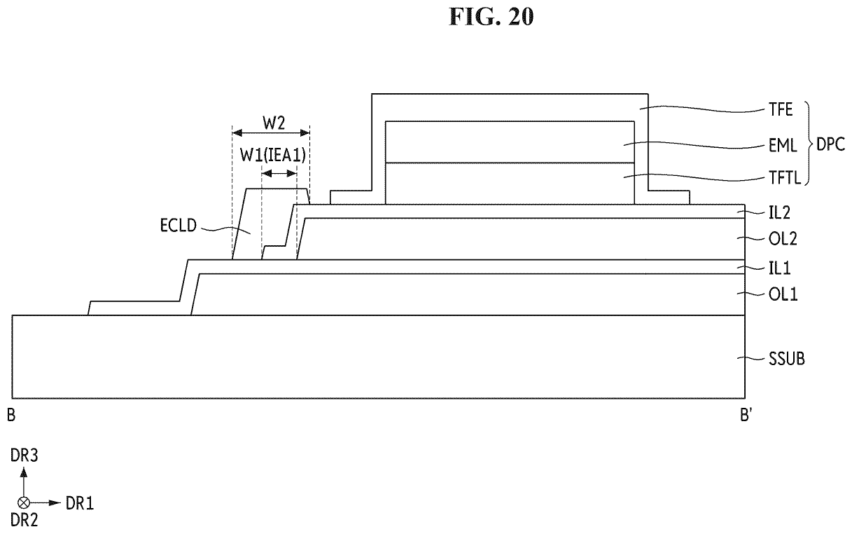

Referring to FIG. 20, a plurality of display cells DPC and the encapsulation cover layer ECLD may be arranged on the second inorganic film IL2. The encapsulation cover layer ECLD may be arranged concurrently (e.g., simultaneously) with the plurality of display cells DPC.

For example, the encapsulation cover layer ECLD may be arranged concurrently (e.g., simultaneously) with at least one planarization film of the plurality of display cells DPC. In one or more embodiments, the encapsulation cover layer ECLD may include substantially the same organic material as the at least one planarization film.

For another example, the encapsulation cover layer ECLD may be arranged together with the pixel-defining layer of the plurality of display cells DPC. In one or more embodiments, the encapsulation cover layer ECLD may include substantially the same organic material as the pixel-defining layer.

For yet another example, the encapsulation cover layer ECLD may be arranged together with the spacer of the plurality of display cells DPC. In one or more embodiments, the encapsulation cover layer ECLD may include substantially the same organic material as the spacer.

Subsequently, the support substrate SSUB may be separated from the first organic film OL1 (step (e.g., act or task) S300 of FIG. 18).

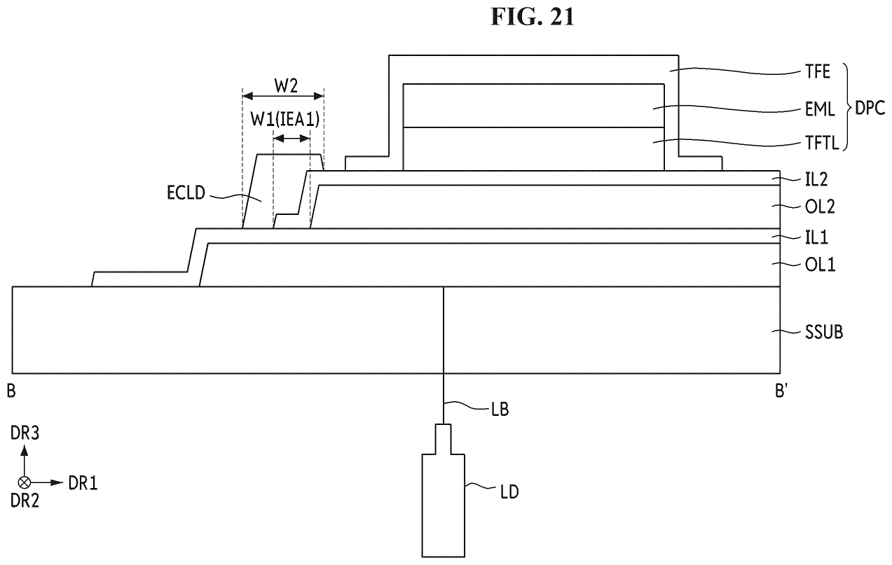

Referring to FIG. 21, before a cutting unit CU is inserted, a carbonization process using laser may be carried out on the first organic film OL1.

The first organic film OL1 may include an organic material having higher heat resistance than the encapsulation cover layer ECLD. The second organic film OL2 may also include an organic material having higher heat resistance than the encapsulation cover layer ECLD. Due to the high heat resistance of the first organic film OL1, if (e.g., when) a carbonization process using laser is carried out on the first organic film OL1 in the thickness direction DR3 of the support substrate SSUB, the encapsulation cover layer ECLD arranged on the first organic film OL1 may not be affected.

If (e.g., when) the encapsulation cover layer ECLD is arranged outside the edge of the first organic film OL1, the encapsulation cover layer ECLD may be exposed to laser and melted during the carbonization process of the first organic film OL1. As a result, the encapsulation cover layer ECLD may be melted and bonded with the first inorganic film IL1, such that particles may be generated due to the melted encapsulation cover layer ECLD while inserting the cutting unit CU and cutting to separate the first organic film OL1 from the support substrate SSUB.

In contrast, if (e.g., when) the encapsulation cover layer ECLD is arranged inside the edge of the first organic film OL1 that includes the organic material having a heat resistance higher than the encapsulation cover layer ECLD as shown in FIG. 21, it may be feasible to prevent the encapsulation cover layer ECLD from being melted (or reduce a degree to or occurrence of which the encapsulation cover layer ECLD is melted) during the carbonization process of the first organic film OL1. As a result, according to one or more embodiments, it may be feasible to prevent particles which may be generated (or reduce a degree to or occurrence of which particles are formed or generated) as the encapsulation cover layer ECLD is melted. For example, initially, the first organic film OL1, the first inorganic film IL1, the second organic film OL2, and the second inorganic film IL2 may be sequentially arranged on a support substrate SSUB (step S100 of FIG. 18). The first organic film OL1 may be arranged on the support substrate SSUB, followed by the first inorganic film IL1, which covers the edge of OL1. The second organic film OL2 may be then arranged on IL1, and the second inorganic film IL2 is arranged on OL2, covering its edge. Subsequently, the plurality of display cells DPC and the encapsulation cover layer ECLD may be arranged on the second inorganic film IL2 (step S200 of FIG. 18). The encapsulation cover layer ECLD may be formed or arranged concurrently (e.g., simultaneously) with the display cells DPC, utilizing substantially the same organic material as the planarization film, the pixel-defining layer, or the spacer. Next, the support substrate SSUB may be separated from the first organic film OL1 (step S300 of FIG. 18). Before inserting the cutting unit CU, the carbonization process utilizing laser may be carried out on OL1. The first organic film OL1 and the second organic film OL2 may have higher heat resistance than the encapsulation cover layer ECLD. If (e.g., when) the encapsulation cover layer ECLD is positioned or arranged outside the edge of the first organic film OL1, it may be exposed to laser and melted during the carbonization process, generating particles if (e.g., when) the cutting unit CU is inserted. In contrast, if (e.gg, when) the encapsulation cover layer ECLD is positioned or arranged inside the edge of the first organic film OL1, it may be feasible to prevent or reduce melting during the carbonization process, thereby reducing particle generation. This may ensure a cleaner separation of the first organic film OL1 from the support substrate SSUB.

If (e.g., when) the carbonization process is carried out, a portion of the surface of the first organic film OL1 that contacts the support substrate SSUB may be carbonized, such that the bonding force between the support substrate SSUB and the first organic film OL1 may become weak. For example, if (e.g., when) the carbonization process is carried out, a portion of the surface of the first organic film OL1 that contacts the support substrate SSUB may be carbonized. This carbonization may weaken the bonding force between the support substrate SSUB and the first organic film OL1, facilitating the separation of the support substrate from the organic film. This step may be desirable in ensuring that the subsequent processes may be performed efficiently or suitably without damaging the display cells or the encapsulation layers. By weakening the bond, the carbonization process may allow for a cleaner and more controlled separation, which is desired or required for maintaining or providing the integrity and performance of the display cells during fabrication.

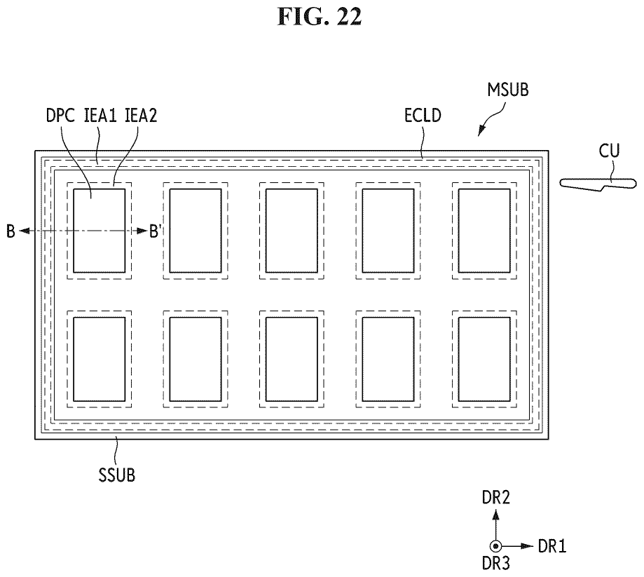

Referring to FIGS. 21 and 22, the cutting unit CU may be inserted between the support substrate SSUB and the first organic film OL1 to separate the support substrate SSUB from the first organic film OL1. Because the bonding force between the support substrate SSUB and the first organic film OL1 is weakened due to carbonization of the first organic film OL1, the support substrate SSUB may be relatively easily separated from the first organic film OL1.

Subsequently, a plurality of display cells DPC may be cut to complete a plurality of display devices (step (e.g., act or task) S400 of FIG. 18).

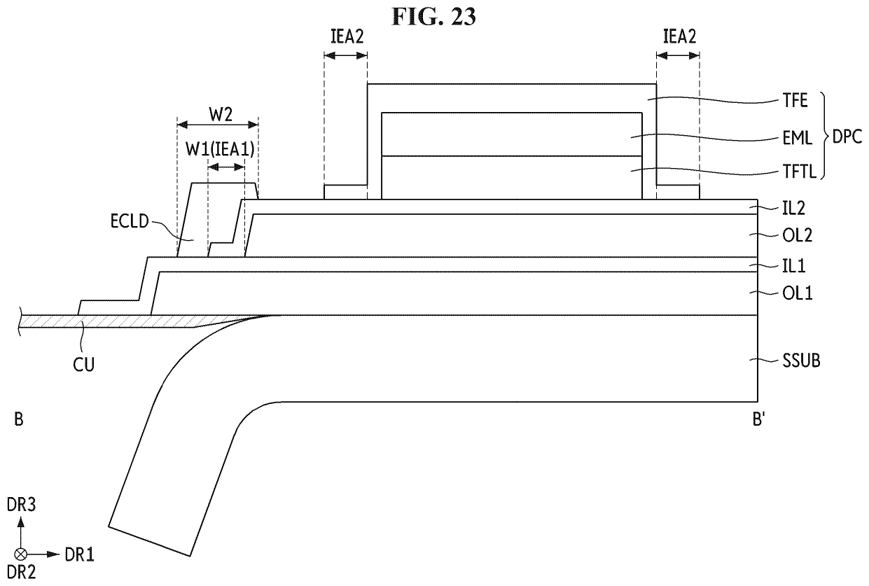

Referring to FIG. 23, the plurality of display cells DPC of the mother substrate MSUB may be cut by using laser LB from a laser device LD and/or a cutting unit. The display devices thus produced may have a structure in which the first organic film OL1, the first inorganic film IL1, the second organic film OL2, the second inorganic film IL2, the thin-film transistor layer TFTL, the light emitting element layer EML, and the encapsulation layer TFE are sequentially stacked.

In the context of the present disclosure and unless defined otherwise, display cells may be the individual units that make up a display panel. Each display cell may contain elements, such as thin-film transistors (TFTs) and light-emitting diodes (LEDs) or liquid crystals, depending on the type of display technology (e.g., OLED and LCD). The display cells may be the building blocks of a display panel, and multiple display cells may be arranged together to form or provide the complete display.

In the context of the present disclosure and unless defined otherwise, a display device refers to the entire assembly that includes the display panel (composed of one or more suitable display cells), along with other components, such as the backlight, the driver electronics, the housing, and/or the touch sensors. Examples of 1 display devices may include televisions, computer monitors, smartphones, and/or tablets.

In the context of the present disclosure and unless defined otherwise, a mother substrate may be used to create multiple display devices. The mother substrate, for example, a large sheet of glass or other material, may act or serve as the base upon which multiple display cells are fabricated. These display cells may be then cut and separated to form or provide individual display panels, which are integrated into one or more suitable electronic devices, such as televisions, monitors, smartphones, and/or tablets. By using a mother substrate, manufacturers may efficiently or suitably produce multiple display panels from a single large sheet, optimizing material usage and production processes. This approach may enhance production efficiency and reduce costs, allowing for the mass production of high-quality display devices.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, and/or a head-mounted display (HMD).

Although one or more embodiments of the present disclosure have been described with reference to the accompanying drawings, those of ordinary skill in the art to which the present disclosure pertains will understand that the subject matter of the present disclosure may be embodied in different forms and should not be construed as being limited to one or more embodiments set forth herein. It therefore will be understood that one or more embodiments described herein are just illustrative but not limitative in all aspects.

What is claimed is:

1. A mother substrate comprising:
a support substrate;
a first organic film on the support substrate;
a first inorganic film arranged on the first organic film and covering an edge of the first organic film;
a second organic film on the first inorganic film;
a second inorganic film arranged on the second organic film and covering an edge of the second organic film;
a plurality of display cells on the second inorganic film; and
an encapsulation cover layer on a first inorganic encapsulation area where the first inorganic film and the second inorganic film contact each other,
wherein the encapsulation cover layer is arranged more inward than the edge of the first organic film on the support substrate.

2. The mother substrate as claimed in claim 1, wherein the encapsulation cover layer does not cover the edge of the first organic film.

3. The mother substrate as claimed in claim 1, wherein the encapsulation cover layer overlaps the edge of the second organic film in a thickness direction of the support substrate.

4. The mother substrate as claimed in claim 1, wherein the encapsulation cover layer overlaps the first organic film in a thickness direction of the support substrate.

5. The mother substrate as claimed in claim 1, wherein the first inorganic encapsulation area is more inward than the edge of the first organic film.

6. The mother substrate as claimed in claim 1, further comprising:
an auxiliary cover layer that is spaced from the encapsulation cover layer and more outward than the edge of the first organic film.

7. The mother substrate as claimed in claim 6, wherein the auxiliary cover layer is on the first inorganic film.

8. The mother substrate as claimed in claim 6, wherein the auxiliary cover layer is more inward than an edge of the first inorganic film.

9. The mother substrate as claimed in claim 1, wherein the encapsulation cover layer comprises:
a first encapsulation cover layer overlapping with the edge of the second organic film in a thickness direction of the support substrate; and
a second encapsulation cover layer spaced from the first encapsulation cover layer and not overlapping with the second organic film in the thickness direction of the support substrate.

10. The mother substrate as claimed in claim 9, wherein the second encapsulation cover layer covers an edge of the second inorganic film.

11. The mother substrate as claimed in claim 1, wherein the encapsulation cover layer comprises an organic material having lower heat resistance than the first organic film.

12. A mother substrate comprising:
a support substrate;
a first organic film on the support substrate;
a first inorganic film arranged on the first organic film and covering an edge of the first organic film;
a second organic film on the first inorganic film;
a second inorganic film arranged on the second organic film and covering an edge of the second organic film;
a plurality of display cells on the second inorganic film; and
an encapsulation cover layer on a first inorganic encapsulation area where the first inorganic film and the second inorganic film contact each other,
wherein the encapsulation cover layer comprises a plurality of encapsulation cover layers spaced from one another, and
wherein the plurality of encapsulation cover layers is arranged more inward than an edge of the first inorganic film and an edge of the second inorganic film on the support substrate or the mother substrate.

13. The mother substrate as claimed in claim 12, wherein the plurality of encapsulation cover layers comprises a first encapsulation cover layer that overlaps the edge of the first organic film in a thickness direction of the support substrate.

14. The mother substrate as claimed in claim 13, wherein the plurality of encapsulation cover layers further comprises a second encapsulation cover layer that is more outward than the edge of the first organic film.

15. The mother substrate as claimed in claim 14, wherein the plurality of encapsulation cover layers comprises: a third encapsulation cover layer that is more inward than the edge of the first organic film.

16. The mother substrate as claimed in claim 15, wherein the first encapsulation cover layer, the second encapsulation cover layer, and the third encapsulation cover layer are spaced from one another.

17. The mother substrate as claimed in claim 15, wherein the first encapsulation cover layer, the second encapsulation cover layer, and the third encapsulation cover layer comprise substantially the same organic material.

18. The mother substrate as claimed in claim 15, wherein the first inorganic encapsulation area comprises:
a first region that contacts the support substrate and is flat;
a second region that contacts the first organic film and is flat; and
a third region that is between the first region and the second region, and
wherein the first encapsulation cover layer is on the first region, the second encapsulation cover layer is on the third region, and the third encapsulation cover layer is on the second region.

19. A method comprising:
sequentially arranging a first organic film, a first inorganic film, a second organic film, and a second inorganic film on a support substrate;
arranging a plurality of display cells and an encapsulation cover layer on the second inorganic film;
separating the support substrate from the first organic film; and
cutting the plurality of display cells,
wherein the arranging of the plurality of display cells and the encapsulation cover layer on the second inorganic film comprises: arranging the encapsulation cover layer on the first inorganic encapsulation area where the first inorganic film not covered by the second organic film and the second inorganic film contact each other,
wherein the encapsulation cover layer is more inward than an edge of the first organic film, and
wherein the method is a method for fabricating a display device.

20. The method as claimed in claim 19, wherein the separating of the support substrate from the first organic film comprises:
inserting a cutting unit between the support substrate and the first organic film; and
cutting, by the cutting unit, between the support substrate and the first organic film along the first organic film.
